(19) United States
(12) Patent Application Publication
(10) Pub. No.: US 2004/0200415 A1
(43) Pub. Date: Oct. 14, 2004

(54) Substrate processing apparatus

(75) Inventors: Tadashi Maegawa, Horikawa-dori (JP); Toshio Hiroe, Horikawa-dori (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/789,870

(22) Filed: Feb. 26, 2004

(30) Foreign Application Priority Data
Feb. 26, 2003 (JP) JP2003-049416
Dec. 22, 2003 (JP) JP2003-425163

(51) Int. Cl. C23C 16/00

(52) U.S. Cl. 118/719

(57) ABSTRACT

A substrate processing apparatus of the present invention is surrounded by a hermetic member, and the internal space thereof is divided by a hermetic member into a rinse and dry processing chamber, a first and second liquid chemical processing chambers, and a substrate transport chamber. Openings for allowing transportation of substrates to and from corresponding chambers are capable of being exposed and blocked by open/close mechanisms including sealing means. Hence, substrates being processed can be transported in an environment isolated from outside an external atmosphere containing oxygen, to thereby suppress formation of unnecessary oxide films or generation of water marks on the surfaces of substrates while being transported. Further, exhaust emission can be reduced, which emission serves to prevent diffusion of an atmosphere containing vapor of a liquid chemical to the outside of the substrate processing apparatus.

### BACKGROUND OF THE INVENTION

1. Field of the Invention

The present invention relates to a substrate processing apparatus for performing predetermined processing on a substrate such as a semiconductor substrate, a glass substrate for liquid crystal display, a glass substrate for a photomask, a substrate for an optical disk or the like.

2. Description of the Background Art

Conventional substrate process steps include dip of a substrate into various types of processing solutions for surface processing of the substrate. FIG. 13 schematically shows an example of a conventional substrate processing apparatus.

With reference to FIG. 13, a substrate processing apparatus 101 mainly comprises a group of processing baths, a dry chamber 120, and a transport mechanism for transporting substrates W. The processing baths include liquid chemical baths 111 and 113 storing a liquid chemical such as an etching solution, and rinse baths 112 and 114 storing pure water as a rinsing solution. The transport mechanism includes up and down mechanisms 131 for dipping the substrates W into each one of the processing baths 111, 112, 113 and 114, and a lateral movement mechanism 132 for carrying the substrates W between the processing baths and the dry chamber 120. The processing baths 111, 112, 113 and 114, and the dry chamber 120 each have six faces surrounded by a chamber 140. The chamber 140 has an upper surface portion provided with an openable/closable door 141 which is normally in a closed state. The openable/closable door 141 is brought to an open state by its cooperative relation with a corresponding up and down mechanism 131 only when the substrates W are to pass through the openable/closable door 141. FIG. 14 is a top plan view of the chamber 140. With reference to FIG. 14, the openable/closable door 141 has a notch 141a to provide an opening to the openable/closable door 141 in a closed state, whereby the openable/closable door 141 even in a closed state allows up and down movement of an arm 131a of the up and down mechanism 131. That is, the atmosphere inside the chamber 140 is not completely isolated from external space and thus is not hermetically sealed even when the openable/closable door 141 is in a closed state. In response, an exhaust mechanism 142 is properly coupled to each one of the chambers 140, whereby air in the chambers 140 is exhausted. Air is continuously exhausted through the exhaust mechanism 142, so that diffusion of an atmosphere containing vapor of a liquid chemical to the outside of the chambers 140 is suppressed.

When the substrates W are subjected to the process in the substrate processing apparatus 101, the unprocessed substrates W transported to the substrate processing apparatus 101 are carried by the up and down mechanisms 131 and the lateral movement mechanism 132, whereby the substrates W are dipped into the liquid chemical bath 111, the rinse bath 112, the liquid chemical bath 113, and the rinse bath 114 in this order. The substrates W are thereafter dried in the dry chamber 120, and are then transported to the outside of the substrate processing apparatus 101.

The foregoing configuration of the conventional apparatus gives rise to the following problems.

First, when the substrates W being processed are carried between the processing baths 111, 112, 113, 114 and the dry chamber 120, the conventional configuration exposes the substrates W to an external atmosphere containing oxygen. This results in formation of unnecessary oxide films on the surfaces of the substrates W, or generation of a defect such as water marks on the surfaces of the substrates W after being subjected to rinsing.

Second, the chambers 140 are not completely isolated from external space and thus, are not hermetically sealed. In response, the conventional configuration requires emissions in large quantities through the exhaust mechanism 142.

Third, the conventional configuration causes a liquid chemical in each processing bath to touch an external atmosphere. This results in shortened lifetime of the liquid chemical, requiring substitute liquid chemicals in large quantities. This problem is encountered especially in the use of a liquid chemical easily oxidized by touching oxygen contained in an external atmosphere, a volatile liquid chemical, a liquid chemical easily degrading by absorbing water content in an external atmosphere, or the like.

Fourth, in transportation of the substrates W, the conventional configuration requires transfer of the substrates W many times between the up and down mechanisms 131 and the lateral movement mechanism 132. This results in an increased risk of dust generation.

### SUMMARY OF THE INVENTION

The present invention is directed to a substrate processing apparatus.

According to the present invention, the substrate processing apparatus comprises: a first processing chamber capable of being isolated from an external atmosphere, the first processing chamber including a liquid chemical processing part for performing liquid chemical process on substrates; a second processing chamber capable of being isolated from an external atmosphere, the second processing chamber including a pure water processing part for performing pure water process on substrates, and a dry processing part for performing dry process on substrates; a first opening provided to an upper portion of the first processing chamber, the first opening allowing substrates to pass therethrough; a first shutter member for exposing and blocking the first opening; a second opening provided to an upper portion of the second processing chamber, the second opening allowing substrates to pass therethrough; a second shutter member for exposing and blocking the second opening; a third opening provided between the first and second processing chambers, the third opening allowing substrates to pass therethrough; a third shutter member for exposing and blocking the third opening; a first transport mechanism for transporting substrates, the first transport mechanism being movable between a position above the first processing chamber and a position above the second processing chamber; a second transport mechanism for carrying substrates between the first and second processing chambers through the third opening; a third transport mechanism for carrying substrates between the position above first processing chamber and the liquid chemical processing part through the first opening, the third transport mechanism also transferring substrates between the first and second transport mechanisms; and a fourth transport mechanism for carrying substrates between the position above the second processing chamber and the pure water processing part through the second opening, the fourth transport mechanism also transferring substrates between the first and second transport mechanisms.

Substrates can be transported in the processing chambers isolated from an external atmosphere containing oxygen during liquid chemical and pure water processes. Formation of unnecessary oxide films on the surfaces of substrates while being transported, or generation of a defect such as water marks on the surfaces of substrates after being subjected to rinsing, is suppressed accordingly. The processing chambers are hermetically sealed inside and isolated from external space. Hence, exhaust emission is reduced, which emission serves to prevent diffusion of an atmosphere containing vapor of a liquid chemical to the outside of the substrate processing apparatus. In the use of a liquid chemical easily oxidized by touching oxygen in an external atmosphere, oxidation of the liquid chemical is suppressed accordingly. In the use of a volatile liquid chemical, further, the amount of volatilization of the liquid chemical is suppressed accordingly. Still further, in the use of a liquid chemical easily degrading by absorbing water content in an external atmosphere, degradation of the liquid chemical is suppressed accordingly. As a result, substitute liquid chemicals are required in less quantities. Additionally, the atmospheres in the first and second processing chambers can be isolated from each other. Exhaust emission is further reduced, which emission serves to prevent diffusion of an atmosphere containing vapor of a liquid chemical to the outside of the substrate processing apparatus. The water content in the atmosphere inside the first processing chamber is also reduced, whereby even a liquid chemical easily degrading by absorbing water content in an external atmosphere is less likely to degrade. As a result, reduction in substitute liquid chemical is realized to a greater degree.

Further, substrates can be subjected to the process flow ending with dry process inside the substrate processing apparatus isolated from an external atmosphere containing oxygen. Hence, exhaust emission is reduced, which emission serves to prevent diffusion of an atmosphere containing vapor of a liquid chemical to the outside of the substrate processing apparatus. Still advantageously, unprocessed substrates are transported in dry condition to the substrate processing apparatus, and processed substrates are transported in dry condition from the substrate processing apparatus. That is, substrates coated with a liquid chemical or water content are never transported outside the substrate processing apparatus. As a result, formation of unnecessary oxide films on the surfaces of substrates, or generation of a defect such as water marks on the surfaces of substrates, is suppressed.

Preferably, the first processing chamber comprises: a liquid chemical processing chamber including the liquid chemical processing part; and a transport chamber provided with the third opening, the transport chamber allowing transportation of substrates by the second transport mechanism, and atmospheres in the liquid chemical processing chamber and the transport chamber can be isolated from each other.

Exhaust emission is reduced further, which emission serves to prevent diffusion of an atmosphere containing vapor of a liquid chemical to the outside of the substrate processing apparatus. Further, the atmosphere in the liquid chemical processing chamber can be isolated with higher reliability from an external atmosphere, whereby a liquid chemical is allowed to have a longer lifetime. As a result, reduction in substitute liquid chemicals is realized to a greater degree.

Still preferably, the substrate processing apparatus further comprises: an inert gas supply member for supplying an inert gas to the first and second processing chambers; and an exhaust member through which air is exhausted from the first and second processing chambers.

The atmosphere within each processing chamber is allowed to be continuously replaced by an inert gas. As a result, formation of unnecessary oxide films on the surfaces of substrates while being transported, or generation of a defect such as water marks on the surfaces of substrates after being subjected to rinsing, is more effectively suppressed. Even in the use of a liquid chemical easily oxidized by touching oxygen in an external atmosphere, or a liquid chemical easily degrading by absorbing water content in an external atmosphere, these liquid chemicals are allowed to have still longer lifetimes. As a result, substitute liquid chemicals are required in still less quantities.

The first, second, third and fourth transport mechanisms can be replaced by a plurality of transport mechanisms in any one of following first, second, third, fourth and fifth alternative transportation modes.

In the first alternative transportation mode, the substrate processing apparatus comprises: a first transport mechanism for transporting substrates, the first transport mechanism being movable between a position above the first processing chamber and a position above the second processing chamber; and a second transport mechanism for carrying substrates between the position above the first processing chamber, the liquid chemical processing part, the pure water processing part, and the position above the second processing chamber while passing through the first, second and third openings, the second transport mechanism also transferring substrates to and from the first transport mechanism.

In the second alternative transportation mode, the substrate processing apparatus comprises: a first transport mechanism for transporting substrates, the first transport mechanism being movable between the first processing chamber, a position above the first processing chamber, a position above the second processing chamber, and the second processing chamber while passing through the first and second openings; and a second transport mechanism for carrying substrates between the liquid chemical processing part and the pure water processing part through the third opening, the second transport mechanism also transferring substrates to and from the first transport mechanism.

In the third alternative transportation mode, the substrate processing apparatus comprises: a first transport mechanism for transporting substrates, the first transport mechanism being movable between the liquid chemical processing part, a position above the first processing chamber, a position above the second processing chamber, and the pure water processing part while passing through the first and second openings; and a second transport mechanism for carrying substrates between the liquid chemical processing part and the pure water processing part through the third opening, the second transport mechanism also transferring substrates to and from the first transport mechanism.

In the fourth alternative transportation mode, the substrate processing apparatus comprises: a first transport mechanism for transporting substrates, the first transport mechanism being movable between the first processing chamber, a position above the first processing chamber, a position above the second processing chamber, and the second processing chamber while passing through the first and second openings; a second transport mechanism for carrying substrates between the first and second processing chambers through the third opening; a third transport mechanism for carrying substrates in the first processing chamber between a position inside the liquid chemical processing part and a position outside the liquid chemical processing part, the third transport mechanism also transferring substrates between the first and second transport mechanisms; and a fourth transport mechanism for carrying substrates in the second processing chamber between a position inside the pure water processing part and a position outside the pure water processing part, the fourth transport mechanism also transferring substrates between the first and second transport mechanisms.

In the fifth alternative transportation mode, the substrate processing apparatus comprises: a first transport mechanism for transporting substrates, the first transport mechanism being movable between the liquid chemical processing part, a position above the first processing chamber, a position above the second processing chamber, and the pure water processing part while passing through the first and second openings; a second transport mechanism for carrying substrates between the first and second processing chambers through the third opening; a third transport mechanism for carrying substrates in the first processing chamber between a position inside the liquid chemical processing part and a position outside the liquid chemical processing part, the third transport mechanism also transferring substrates between the first and second transport mechanisms; and a fourth transport mechanism for carrying substrates in the second processing chamber between a position inside the pure water processing part and a position outside the pure water processing part, the fourth transport mechanism also transferring substrates between the first and second transport mechanisms.

It is therefore an object of the present invention to provide a substrate processing apparatus capable of both suppressing formation of unnecessary oxide films or generation of water marks on the surfaces of substrates, and reducing exhaust emission during process flow of the substrates. The present invention is also intended to provide a substrate processing apparatus exhibiting excellence especially in reduction in substitute liquid chemicals and reduction in probability of dust generation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view of the internal configuration of a substrate processing apparatus according to the present invention;

FIG. 2 is a plan sectional view taken along a line II-II of FIG. 1;

FIG. 3 is a plan sectional view taken along a line III-III of FIG. 1;

FIG. 4 is a conceptual view of a configuration including pipes and the like which accompany the substrate processing apparatus of FIG. 1;

FIG. 5 is a block diagram showing the electrical structure of the substrate processing apparatus of FIG. 1;

FIG. 6 shows a transport path of substrates in the substrate processing apparatus of FIG. 1;

FIG. 7 schematically shows a substrate processing apparatus which comprises one liquid chemical processing chamber containing one liquid chemical bath inside;

FIG. 8 shows a first alternative transportation mode;

FIG. 9 shows a second alternative transportation mode;

FIG. 10 shows a third alternative transportation mode;

FIG. 11 shows a fourth alternative transportation mode;

FIG. 12 shows a fifth alternative transportation mode;

FIG. 13 shows an exemplary conventional substrate processing apparatus; and

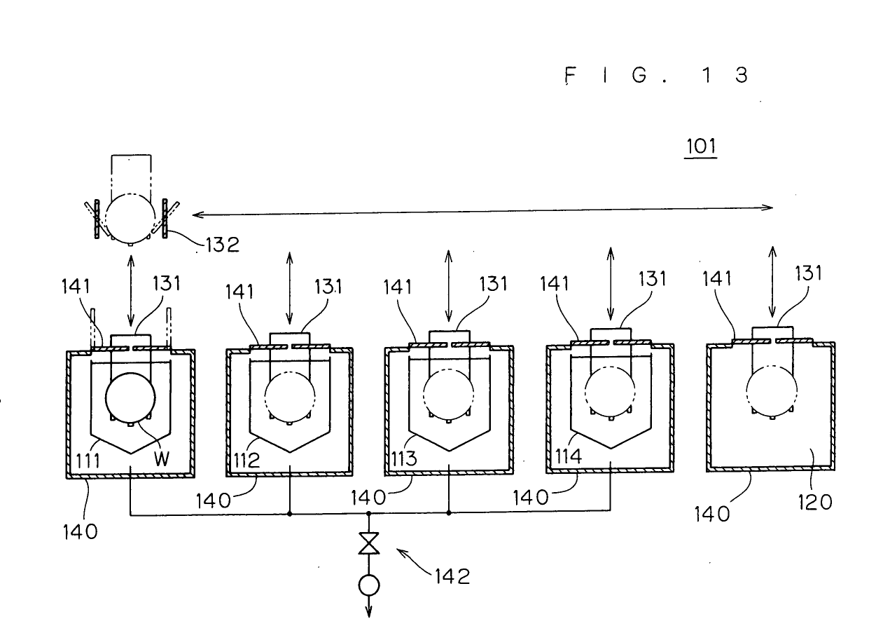

FIG. 14 is a top plan view of one chamber of the substrate processing apparatus of FIG. 13.

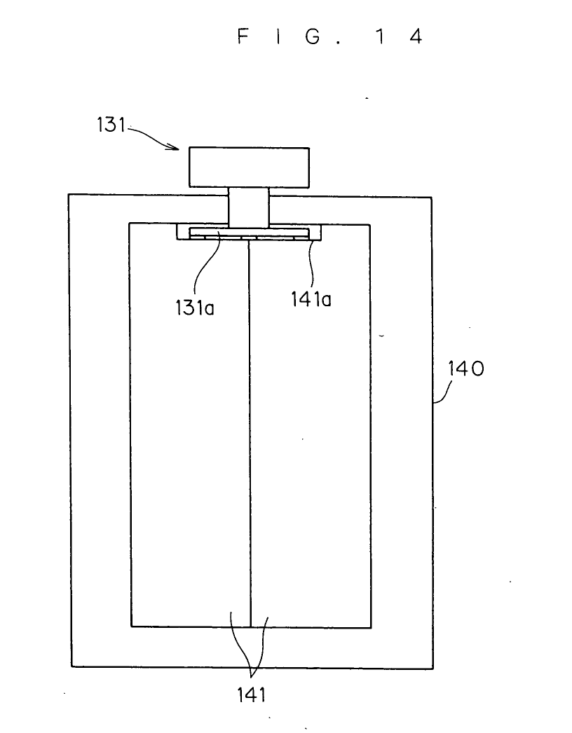

### DESCRIPTION OF THE PREFERRED EMBODIMENTS

The preferred embodiment of the present invention will be described in detail with reference to the drawings.

<1. Major Configuration of Substrate Processing Apparatus 1>

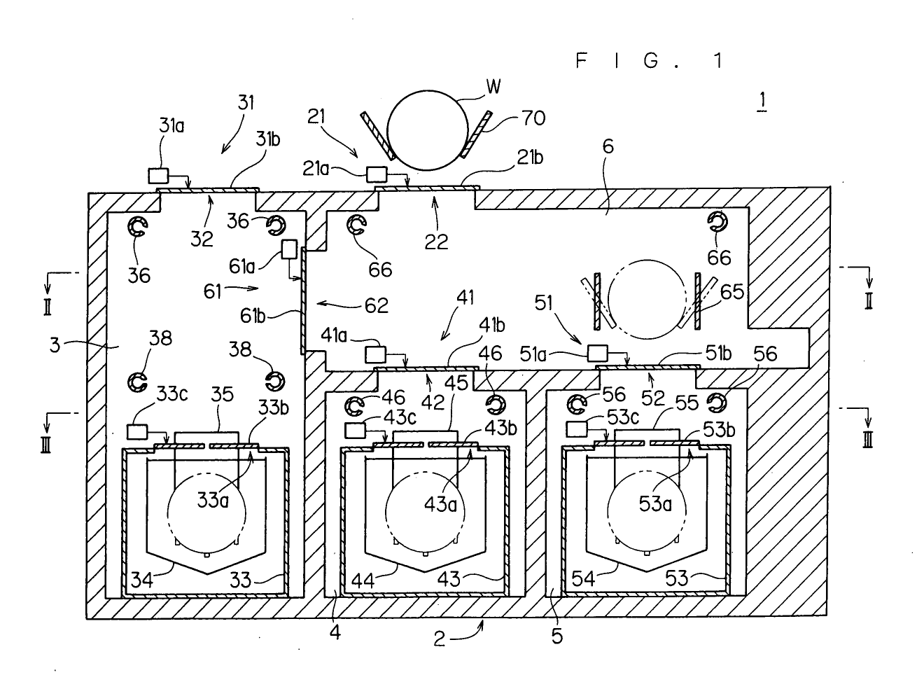

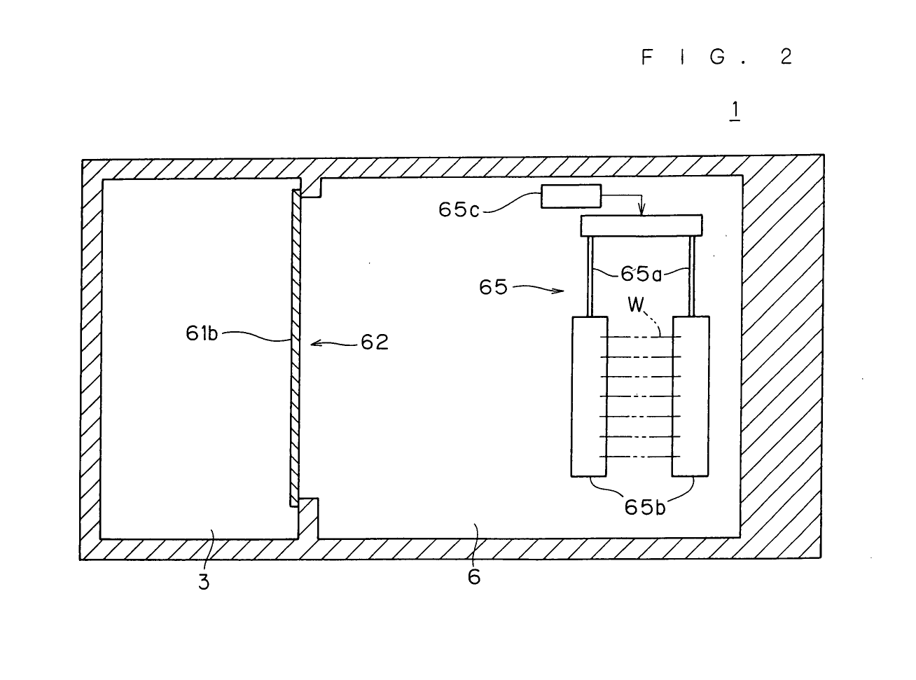

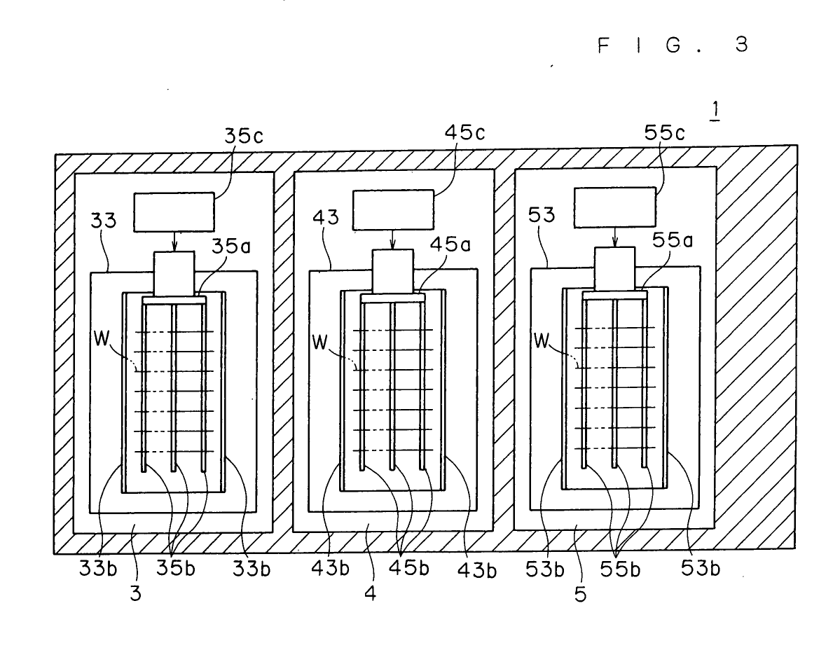

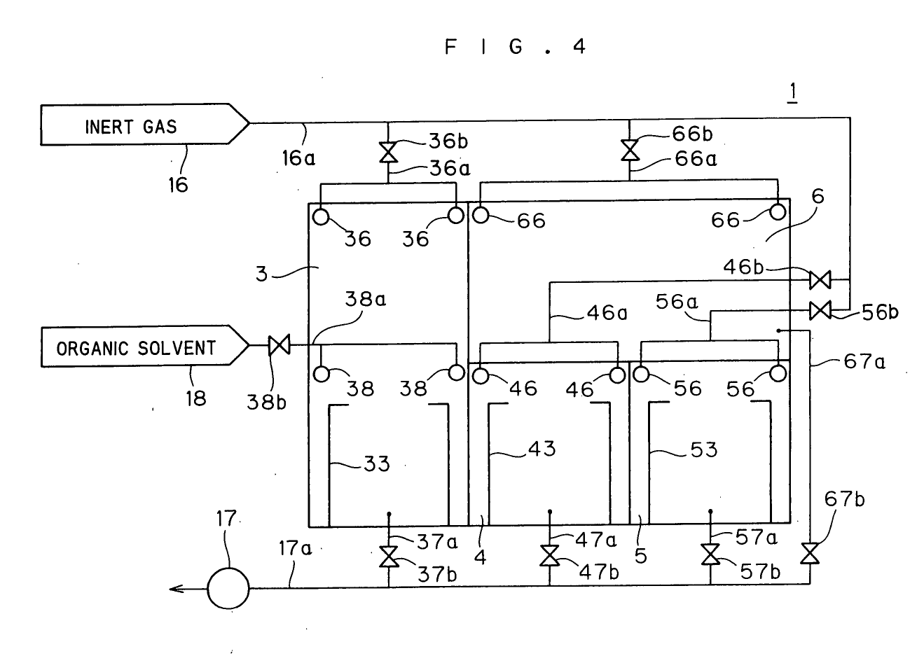

FIG. 1 is a longitudinal sectional view of the internal configuration of a substrate processing apparatus 1 according to a preferred embodiment of the present invention. FIGS. 2 and 3 are plan sectional views taken along lines II-II and III-III of FIG. 1, respectively. FIG. 4 is a conceptual view of a configuration including pipes and the like which accompany the substrate processing apparatus 1. With reference to FIGS. 1 through 4, the apparatus configuration of the substrate processing apparatus 1 will be discussed first.

The substrate processing apparatus 1 is operative to transport a plurality of substrates W (hereinafter simply referred to as “substrates W”) together, and to provide liquid chemical process, rinsing (pure water process), and dry process to the substrates W. the substrate processing apparatus 1 is mainly composed of a liquid chemical processing chamber (first processing chamber) 2, and a rinse and dry processing chamber (second processing chamber) 3. The liquid chemical processing chamber 2 and the rinse and dry processing chamber 3 both have an approximately box-like shape surrounded by a hermetic member, and are contiguous to each other in one piece. The hermetic member on the border between the liquid chemical processing chamber 2 and the rinse and dry processing chamber 3 will be referred to as a first partition member.

The upper surface of the liquid chemical processing chamber 2 is provided with a substrate inlet 22 capable of opening and closing by an open/close mechanism 21. The substrate inlet 22 is arranged vertically above an opening 42 to be discussed later. The open/close mechanism 21 comprises an actuator 21 a conceptually shown in FIG. 1, and a sliding door 21b capable of opening and closing by the actuator 21a. The sliding door 21b includes sealing means such as an O-ring. The open/close mechanism 21 in a closed state isolates the atmosphere within the liquid chemical processing chamber 2 from the atmosphere outside the substrate processing apparatus 1. The open/close mechanism 21 in an open state allows transportation of the substrates W to the substrate processing apparatus 1 through the substrate inlet 22.

The upper surface of the rinse and dry processing chamber 3 is provided with a substrate outlet 32 capable of opening and closing by an open/close mechanism 31. The open/close mechanism 31 comprises an actuator 31a conceptually shown in FIG. 1, and a sliding door 31b capable of opening and closing by the actuator 31a. The sliding door 31b includes sealing means such as an O-ring. The open/close mechanism 31 in a closed state isolates the atmosphere within the rinse and dry processing chamber 3 from the atmosphere outside the substrate processing apparatus 1. The open/close mechanism 31 in an open state allows transportation of the substrates W from the substrate processing apparatus 1 through the substrate outlet 32.

That is, the open/close mechanisms 31 and 32 both in a closed state isolate the internal space of the substrate processing apparatus 1 (including the processing chambers) from external space.

The liquid chemical processing chamber 2 is divided by a hermetic partition member into a first liquid chemical processing chamber 4, a second liquid chemical processing chamber 5, and a substrate transport chamber 6. The first and second liquid chemical processing chambers 4 and 5 are contiguous to each other. The substrate transport chamber 6 is arranged over the first and second liquid chemical processing chambers 4 and 5. The hermetic member on the border between the first and second liquid chemical processing chambers 4 and 5, and the substrate transport chamber 6 will be referred to as a second partition member. The hermetic member on the border between the first and second liquid chemical processing chambers 4 and 5 will be referred to as a third partition member.

The partition member between the first liquid chemical processing chamber 4 and the substrate transport chamber 6 is provided with the opening 42 capable of being exposed and blocked by an open/close mechanism 41. The open/close mechanism 41 comprises an actuator 41a conceptually shown in FIG. 1, and a sliding door 41b capable of opening and closing by the actuator 41a. The sliding door 41b includes sealing means such as an O-ring. The open/close mechanism 41 in a closed state isolates the atmosphere within the first liquid chemical processing chamber 4 from the atmosphere within the substrate transport chamber 6. The open/close mechanism 41 in an open state allows transportation of the substrates W through the opening 42.

The partition member between the second liquid chemical processing chamber 5 and the substrate transport chamber 6 is provided with an opening 52 capable of being exposed and blocked by an open/close mechanism 51. The open/close mechanism 51 comprises an actuator 51a conceptually shown in FIG. 1, and a sliding door 51b capable of opening and closing by the actuator 51a. The sliding door 51b includes sealing means such as an O-ring. The open/close mechanism 51 in a closed state isolates the atmosphere within the second liquid chemical processing chamber 5 from the atmosphere within the substrate transport chamber 6. The open/close mechanism 51 in an open state allows transportation of the substrates W through the opening 52.

The partition member between the substrate transport chamber 6 and the rinse and dry processing chamber 3 is provided with an opening 62 capable of being exposed and blocked by an open/close mechanism 61. The open/close mechanism 61 comprises an actuator 61a conceptually shown in FIG. 1, and a sliding door 61b capable of opening and closing by the actuator 61a. The sliding door 61b includes sealing means such as an O-ring. The open/close mechanism 61 in a closed state isolates the atmosphere within the liquid chemical processing chamber 2 from the atmosphere within the rinse and dry processing chamber 3. The open/close mechanism 61 in an open state allows transportation of the substrates W through the opening 62.

The first liquid chemical processing chamber 4 comprises an approximately box-shaped casing 43 inside which contains a first liquid chemical bath 44. The first liquid chemical bath 44 stores a liquid chemical such as an etching solution into which the substrates W transported to the substrate processing apparatus 1 are desired to be dipped first. The upper surface portion of the casing 43 is provided with an opening 43a so sized to allow the substrates W to pass therethrough, and a door 43b which allows the opening 43a to be exposed and blocked. The door 43b is capable of opening and closing in a double-hinged manner by an actuator 43c conceptually shown in FIG. 1. The door 43b is in a closed state in FIG. 1, whereas it is in an open state in FIG. 3.

The second liquid chemical processing chamber 5 comprises an approximately box-shaped casing 53 inside which contains a second liquid chemical bath 54. The second liquid chemical bath 54 stores a liquid chemical into which the substrates W after being subjected to dip into the first liquid chemical bath 44 are desired to be dipped. The upper surface portion of the casing 53 is provided with an opening 53a so sized to allow the substrates W to pass therethrough, and a door 53b which allows the opening 53a to be exposed and blocked. The door 53b is capable of opening and closing in a double-hinged manner by an actuator 53c conceptually shown in FIG. 1. The door 53b is in a closed state in FIG. 1, whereas it is in an open state in FIG. 3.

The rinse and dry processing chamber 3 is provided with an approximately box-shaped casing 33 inside. The casing 33 contains a rinse bath 34 storing pure water. The upper surface portion of the casing 33 is provided with an opening 33a so sized to allow the substrates W to pass therethrough, and a door 33b which allows the opening 33a to be exposed and blocked. The door 33b is capable of opening and closing in a double-hinged manner by an actuator 33c conceptually shown in FIG. 1. The door 33b is in a closed state in FIG. 1, whereas it is in an open state in FIG. 3.

As the above-discussed actuators 21a, 31a, 41a, 51a, 61a, 33c, 43c and 53c, various types of known mechanisms such as an air cylinder are applicable.

For transportation of the substrates W, the substrate processing apparatus 1 comprises two transport mechanisms including 65 and 70, and three up and down mechanisms including 35, 45 and 55.

With reference to FIG. 2, the transport mechanism 65 has a pair of axes 65a extending in a direction orthogonal to the main surfaces of the substrates W, and a pair of holding plates 65b arranged via the axes 65a. The holding plates 65b are rotatable about the corresponding axes 65a. The holding plates 65b each have a plurality of grooves (not shown) on the inner surface into which the outer peripheries of the substrates W are fitted, whereby the substrates W in an upright posture are held from both sides between the holding plates 65b. By means of a drive mechanism 65c conceptually shown in FIG. 2, the pair of holding plates 65b and the pair of axes 65a are integrally allowed to move laterally inside the substrate transport chamber 6 in a direction in which the first and second liquid chemical baths 44 and 54 are arranged. By means of stretch of the drive mechanism 65c, for example, the pair of holding plates 65b and the pair of axes 65a are allowed to move laterally, entering into the rinse and dry processing chamber 3. That is, while holding the substrates W, the transport mechanism 65 is capable of moving laterally between a position for transferring the substrates W to and from the up and down mechanism 35, a position for transferring the substrates W to and from the up and down mechanism 45, and a position for transferring the substrates W to and from the up and down mechanism 35 in the rinse and dry processing chamber 3.

Similar to the transport mechanism 65, the transport mechanism 70 has a pair of axes, and a pair of holding plates rotatable about the axes. The substrates W are fitted into a plurality of grooves inside the pair of holding plates, whereby the substrates W in an upright posture are held from both sides between the holding plates. The transport mechanism 70 serves to transport the substrates W to and from another apparatus, and moves between a position above the liquid chemical processing chamber 2 and a position above the rinse and dry processing chamber 3. The transport mechanism 70 also serves to transfer the substrates W above the substrate outlet 32 to and from the up and down mechanism 35 discussed below, and to transfer the substrates W above the substrate inlet 22 to and from the up and down mechanism 45 discussed below. The transport mechanism 70 further serves to transfer the substrates W to and from a substrate inlet and outlet not shown.

With reference to FIG. 3, the up and down mechanism 35 has an arm 35a, and three holding rods 35b fixed to the arm 35a. The holding rods 35b all extend in a direction orthogonal to the main surfaces of the substrates W. The holding rods 35b each have a plurality of grooves (not shown) into which the outer peripheries of the substrates W are fitted, whereby the substrates W in an upright posture are held on the holding rods 35b. By means of a drive mechanism 35c conceptually shown in FIG. 3, the arm 35a and the three holding rods 35b are integrally allowed to move up and down inside the rinse and dry processing chamber 3. By means of stretch of the drive mechanism 35c or the arm 35a, for example, the arm 35a and the three holding rods 35b are allowed to move up through the substrate outlet 32 to reach a position above the substrate outlet 32. That is, while holding the substrates W thereon, the up and down mechanism 35 is capable of moving up and down between a position for dipping the substrates W into the rinse bath 34, and a position above the substrate outlet 32 allowing transfer of the substrates W to and from the transport mechanism 70.

With reference to FIG. 3, the up and down mechanism 45 has an arm 45a, and three holding rods 45b fixed to the arm 45a. The holding rods 45b all extend in a direction orthogonal to the main surfaces of the substrates W. The holding rods 45b each have a plurality of grooves (not shown) into which the outer peripheries of the substrates W are fitted, whereby the substrates W in an upright posture are held on the holding rods 45b. By means of a drive mechanism 45c conceptually shown in FIG. 3, the arm 45a and the three holding rods 45b are integrally allowed to move up and down inside the first liquid chemical processing chamber 4. By means of stretch of the drive mechanism 45c or the arm 45a, for example, the arm 45a and the three holding rods 45b are allowed to move up through the opening 42 into the substrate transport chamber 6, further moving up through the substrate inlet 22 to reach a position above the substrate inlet 22. That is, while holding the substrates W thereon, the up and down mechanism 45 is capable of moving up and down between a position for dipping the substrates W into the first liquid chemical bath 44, a position allowing transfer of the substrates W to and from the transport mechanism 65 in the substrate transport chamber 6, and a position above the substrate inlet 22 allowing transfer of the substrates W to and from the transport mechanism 70.

With reference to FIG. 3, the up and down mechanism 55 has an arm 55a, and three holding rods 55b fixed to the arm 55a. The holding rods 55b all extend in a direction orthogonal to the main surfaces of the substrates W. The holding rods 55b each have a plurality of grooves (not shown) into which the outer peripheries of the substrates W are fitted, whereby the substrates W in an upright posture are held on the holding rods 55b. By means of a drive mechanism 55c conceptually shown in FIG. 3, the arm 55a and the three holding rods 55b are integrally allowed to move up and down inside the second liquid chemical processing chamber 5. By means of stretch of the drive mechanism 55c or the arm 55a, for example, the arm 55a and the three holding rods 55b are allowed to move up through the opening 52 to enter into the substrate transport chamber 6. That is, while holding the substrates W thereon, the up and down mechanism 55 is capable of moving up and down between a position for dipping the substrates W into the second liquid chemical bath 54, and a position allowing transfer of the substrates W to and from the transport mechanism 65 in the substrate transport chamber 6.

As the respective drive mechanisms 35c, 45c, 55c and 65c of the up and down mechanisms 35, 45, 55 and the transport mechanism 65, various types of known mechanisms are applicable such as a mechanism for transmitting rotating actuation of a motor as a vertical or lateral movement through a pulley and a belt, for example, or a mechanism for transmitting rotating actuation of a motor as a vertical or lateral movement through a ball screw.

The transport mechanism 65 and 70 hold the substrates W in an upright posture from the sides, whereas the up and down mechanisms 35, 45 and 55 hold the substrates W in an upright posture from underneath. Hence, the substrates W can be transferred to and from the transport mechanisms 65 and 70, and the up and down mechanisms 35, 45 and 55 without interference therebetween.

The rinse and dry processing chamber 3, the first and second liquid chemical processing chambers 4 and 5, and the substrate transport chamber 6 are respectively provided with inert gas supply nozzles 36, 46, 56 and 66. With reference to FIG. 4, the inert gas supply nozzles 36, 46, 56 and 66 are communicatively connected to pipes 36a, 46a, 56a and 66a, respectively. The pipes 36a, 46a, 56a and 66a are communicatively connected to a common pipe 16a through valves 36b, 46b, 56b and 66b, respectively. The pipe 16a has another end communicatively connected to an inert gas supply source 16. When the valves 36b, 46b, 56b and 66b are brought to an open state, an inert gas such as nitrogen gas is supplied accordingly to respective internal spaces of the rinse and dry processing chamber 3, the first and second liquid chemical processing chambers 4 and 5, and the substrate transport chamber 6.

With reference to FIG. 4, exhaust ducts 37a, 47a, 57a and 67a are respectively connected to the casings 33, 43, 53 and the substrate transport chamber 6. The exhaust ducts 37a, 47a, 57a and 67a are communicatively connected to a common pipe 17a through valves 37b, 47b, 57b and 67b, respectively. An exhaust pump 17 is interposed in the pipe 17a. Accordingly, the valves 37b, 47b, 57b and 67b brought in an open state respectively exhaust air from the rinse and dry processing chamber 3, the first and second liquid chemical processing chambers 4 and 5, and the substrate transport chamber 6.

The rinse and dry processing chamber 3 is further provided with organic solvent supply nozzles 38. With reference to FIG. 4, the organic solvent supply nozzles 38 are communicatively connected to a pipe 38a which is further communicatively connected through a valve 38b to an organic solvent supply source 18. When the valve 38b is brought to an open state, vapor of an organic solvent such as isopropyl alcohol is supplied accordingly to the internal space of the rinse and dry processing chamber 3, whereby the substrates W raised from the rinse bath 34 undergo dry process using the organic solvent.

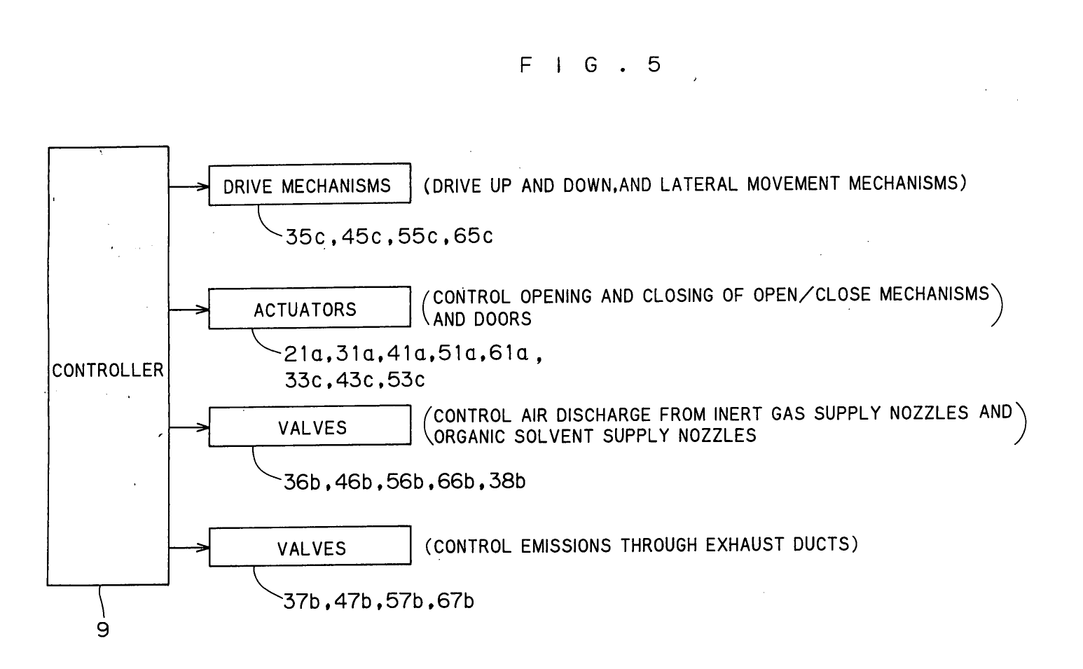

FIG. 5 is a block diagram showing the electrical structure of the substrate processing apparatus 1. A controller 9 comprising a microcomputer, for example, electrically controls the drive mechanisms 35c, 45c, 55c and 65c, whereby the drive mechanisms 35c, 45c, 55c and 65c respectively drive and control actuation of the up and down mechanisms 35, 45, 55 and the transport mechanism 65. In cooperation with the control of the drive mechanisms 35c, 45c, 55c and 65c, the controller 9 further electrically controls the actuators 21a, 31a, 41a, 51a, 61a, 33c, 43c and 53c, whereby the actuators 21a, 31a, 41a, 51a and 61a, and 33c, 43c and 53c respectively bring the open/close mechanisms 21, 31, 41, 51 and 61, and the doors 33b, 43b and 53b to an open state only when any one of the up and down mechanisms 35, 45, 55 and the transport mechanism 65 is to pass therethrough. In other cases, the actuators 21a, 31a, 41a, 51a and 61a, and 33c, 43c and 53c respectively bring the open/close mechanisms 21, 31, 41, 51 and 61, and the doors 33b, 43b and 53b to a closed state. The controller 9 also electrically controls opening and closing of the valves 36b, 46b, 56b, 66b and 38b, whereby the amounts of air discharge from the inert gas supply nozzles 36, 46, 56, 66 and the organic solvent supply nozzle 38 are respectively controlled. The controller 9 still further electrically controls opening and closing of the valves 37b, 47b, 57b and 67b, whereby emissions through the exhaust ducts 37a, 47a, 57a and 67a are respectively controlled.

<2. Process Flow in Substrate Processing Apparatus 1>

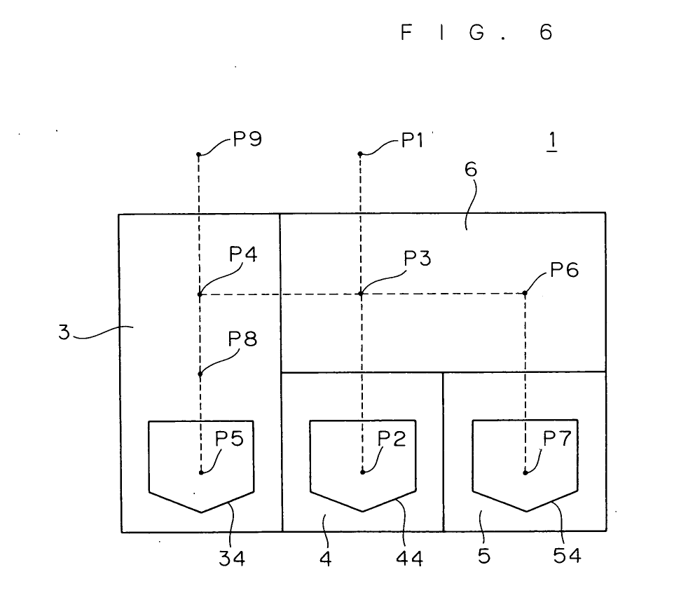

FIG. 6 shows by dashed lines a transport path of the substrates W in the substrate processing apparatus 1. With reference to FIGS. 1 and 6, the process flow in the substrate processing apparatus 1 will be discussed. As seen from the foregoing, the open/close mechanisms 21, 31, 41, 51 and 61, and the doors 33b, 43b and 53b are brought to an open state only when any one of the up and down mechanisms 35, 45, 55 and the transport mechanism 65 is to pass therethrough. In other cases, the open/close mechanisms 21, 31, 41, 51 and 61, and the doors 33b, 43b and 53b are in a closed state. The inert gas supply nozzles 36, 46, 56 and 66 each continuously supply a predetermined amount of inert gas. A predetermined amount of air is continuously exhausted through each one of the exhaust ducts 37a, 47a, 57a and 67a.

When the substrates W are to be processed in the substrate processing apparatus 1, the unprocessed substrates W are transported first by the transport mechanism 70 to a position P1 above the substrate inlet 22. Next, the up and down mechanism 45 moves up through the opening 42 and the substrate inlet 22 to the position P1. The transport mechanism 70 thereafter releases the substrates W and the up and down mechanism 45 receives the substrates W from underneath, whereby the substrates W are transferred from the transport mechanism 70 to the up and down mechanism 45 at the position P1.

The up and down mechanism 45 holding the substrates W thereon then moves down through the substrate inlet 22 and the opening 42 to a position P2 in the first liquid chemical bath 44, at which the substrates W are dipped into a liquid chemical stored in the first liquid chemical bath 44. The up and down mechanism 45 is brought to a standstill or oscillates at the position P2 for a certain period of time, whereby the substrates W are subjected to liquid chemical process.

During the liquid chemical process in the first liquid chemical bath 44, the transport mechanism 65 moves to a position P3 above the opening 42 and is placed in standby at the position P3. At the time when a certain period of time has elapsed and the liquid chemical process in the first liquid chemical bath 44 is finished, the up and down mechanism 45 holding the substrates W thereon moves up through the opening 42 to reach the position P3 in the substrate transport chamber 6. By means of rotation of the holding plates 65b, the transport mechanism 65 receives the substrates W held on the up and down mechanism 45, whereby the substrates W are transferred from the up and down mechanism 45 to the transport mechanism 65 at the position P3. After transfer of the substrates W to the transport mechanism 65, the up and down mechanism 45 moves down to a position that does not interfere with lateral movement of the transport mechanism 65.

The transport mechanism 65 holding the substrates W laterally moves through the opening 62 to a position P4 in the rinse and dry processing chamber 3. Next, the up and down mechanism 35 moves up to the position P4. By means of rotation of the holding plates 65b, the transport mechanism 65 releases the substrates W and the up and down mechanism 35 receives the substrates W from underneath, whereby the substrates W are transferred from the transport mechanism 65 to the up and down mechanism 35 at the position P4.

The up and down mechanism 35 holding the substrates W thereon moves down to a position P5 in the rinse bath 34, at which the substrates W are dipped into pure water stored in the rinse bath 34. The up and down mechanism 35 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the up and down mechanism 35 holding the substrates W thereon rises up to the position P4 where the transport mechanism 65 is placed in standby. By means of rotation of the holding plates 65b, the transport mechanism 65 receives the substrates W held on the up and down mechanism 35, whereby the substrates W are transferred from the up and down mechanism 35 to the transport mechanism 65 at the position P4. After transfer of the substrates W to the transport mechanism 65, the up and down mechanism 35 moves down to a position that does not interfere with lateral movement of the transport mechanism 65.

The transport mechanism 65 holding the substrates W laterally moves through the opening 62 to a position P6 in the substrate transport chamber 6 above the opening 52. Next, the up and down mechanism 55 moves up to the position P6. By means of rotation of the holding plates 65b, the transport mechanism 65 releases the substrates W and the up and down mechanism 55 receives the substrates W from underneath, whereby the substrates W are transferred from the transport mechanism 65 to the up and down mechanism 55 at the position P6.

The up and down mechanism 55 holding the substrates W thereon moves down through the opening 52 to a position P7 in the second liquid chemical bath 54, at which the substrates W are dipped into a liquid chemical stored in the second liquid chemical bath 54. The up and down mechanism 55 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the up and down mechanism 55 holding the substrates W thereon moves up through the opening 52 to the position P6 where the transport mechanism 65 is placed in standby. By means of rotation of the holding plates 65b, the transport mechanism 65 receives the substrates W held on the up and down mechanism 55, whereby the substrates W are transferred from the up and down mechanism 55 to the transport mechanism 65 at the position P6. After transfer of the substrates W to the transport mechanism 65, the up and down mechanism 55 moves down to a position that does not interfere with lateral movement of the transport mechanism 65.

The transport mechanism 65 holding the substrates W laterally moves through the opening 62 to the position P4 in the rinse and dry processing chamber 3. Next, the up and down mechanism 35 moves up to the position P4. By means of rotation of the holding plates 65b, the transport mechanism 65 releases the substrates W and the up and down mechanism 35 receives the substrates W from underneath, whereby the substrates W are transferred from the transport mechanism 65 to the up and down mechanism 35 at the position P4.

The up and down mechanism 35 holding the substrates W thereon moves down to the position P5 in the rinse bath 34, at which the substrates W are dipped into pure water stored in the rinse bath 34. The up and down mechanism 35 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the up and down mechanism 35 holding the substrates W thereon rises up to a position P8 between the organic solvent supply nozzles 38, at which the substrates W are subjected to dry process by means of supply of vapor of an organic solvent from the organic solvent supply nozzles 38. This dry process proceeds with condensation of vapor of the supplied organic solvent on the surfaces of the substrates W, and evaporation of this vapor together with water content in the surfaces of the substrates W.

At the time when the dry process of the substrates W is finished, the up and down mechanism 35 holding the substrates W thereon moves up through the substrate outlet 32 to a position P9 above the substrate outlet 32. The processed substrates W are then transferred from the up and down mechanism 35 to the transport mechanism 70 placed in standby at the position P9. A series of processes in the substrate processing apparatus 1 thereby ends.

As discussed, in the substrate processing apparatus 1 of the present preferred embodiment, the substrates W can be transported in the rinse and dry processing chamber 3, in the first and second liquid chemical processing chambers 4 and 5, and in the substrate transport chamber 6 isolated from an external atmosphere containing oxygen during liquid chemical process, rinsing, and dry process. Formation of unnecessary oxide films on the surfaces of the substrates W while being transported, or generation of a defect such as water marks on the surfaces of the substrates W after being subjected to rinsing, is suppressed accordingly. The substrate processing apparatus 1 is hermetically sealed inside and isolated from external space. Hence, emissions through the exhaust ducts 47a and 57a are reduced, which emissions serve to prevent diffusion of an atmosphere containing vapor of a liquid chemical to the outside of the substrate processing apparatus 1. In the use of a liquid chemical easily oxidized by touching oxygen in an external atmosphere, oxidation of the liquid chemical is suppressed accordingly. In the use of a volatile liquid chemical, further, the amount of volatilization of the liquid chemical is suppressed accordingly. Still further, in the use of a liquid chemical easily degrading by absorbing water content in an external atmosphere, degradation of the liquid chemical is suppressed accordingly. As a result, substitute liquid chemicals are required in less quantities.

In the substrate processing apparatus 1 of the present preferred embodiment, a hermetic partition member surrounds the rinse and dry processing chamber 3, and the first and second liquid chemical processing chambers 4 and 5. The opening through which the substrates W are transported to and from each processing chamber is capable of being blocked by the open/close mechanism including sealing means. Hence, emissions through the exhaust ducts 47a and 57a are further reduced, which emissions serve to prevent diffusion of an atmosphere containing vapor of a liquid chemical to the outside of the apparatus. The water content in the atmosphere inside the first or second liquid chemical processing chambers 4 or 5 is reduced, whereby even a liquid chemical easily degrading by absorbing water content in an external atmosphere is allowed to have a longer lifetime. As a result, reduction in substitute liquid chemicals is realized to a greater degree.

The substrate processing apparatus 1 of the present preferred embodiment characteristically comprises the inert gas supply nozzles 36, 46, 56 and 66 for supplying an inert gas inside the rinse and dry processing chamber 3, the first and second liquid chemical processing chambers 4 and 5, and the substrate transport chamber 6, respectively. The substrate processing apparatus 1 of the present preferred embodiment also characteristically comprises the exhaust ducts 37a, 47a, 57a and 67a through which air is exhausted from the rinse and dry processing chamber 3, the first and second liquid chemical processing chambers 4 and 5, and the substrate transport chamber 6, respectively. Hence, the atmosphere within each processing chamber is allowed to be continuously replaced by an inert gas. As a result, formation of unnecessary oxide films on the surfaces of the substrates W while being transported, or generation of a defect such as water marks on the surfaces of the substrates W after being subjected to rinsing, is suppressed with higher reliability. Even in the use of a liquid chemical easily oxidized by touching oxygen in an external atmosphere, or a liquid chemical easily degrading by absorbing water content in an external atmosphere, these liquid chemicals are allowed to have still longer lifetimes. As a result, substitute liquid chemicals are required in still less quantities.

In the substrate processing apparatus 1 of the present preferred embodiment, the substrates W can be subjected to the process flow ending with dry process inside the substrate processing apparatus 1 isolated from an external atmosphere containing oxygen. Hence, the unprocessed substrates W are transported in dry condition to the substrate processing apparatus 1, and the processed substrates W are transported in dry condition from the substrate processing apparatus 1. That is, the substrates W coated with a liquid chemical or water content are never transported outside the substrate processing apparatus 1. As a result, formation of unnecessary oxide films on the surfaces of the substrates W, or generation of a defect such as water marks on the surfaces of the substrates W, is suppressed.

<3. Modifications>

The present invention is not limited to the exemplary preferred embodiment discussed above.

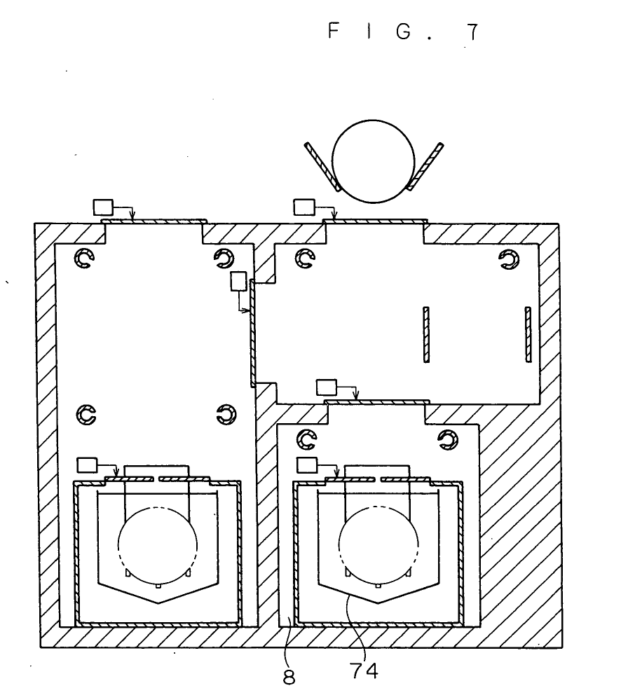

In the foregoing preferred embodiment, the first and second liquid chemical processing chambers 4 and 5 respectively contain the first and second liquid chemical baths 44 and 54. As an example, with reference to FIG. 7, a substrate processing apparatus alternatively comprises one chemical processing chamber 8 which contains one liquid chemical bath 74 inside. Further alternatively, a substrate processing apparatus may comprise three or more liquid chemical processing chambers which contain respective liquid chemical baths inside. Still alternatively, a substrate processing apparatus may comprise two or more rinse baths prepared for corresponding liquid chemicals to be washed away.

In the foregoing preferred embodiment, a predetermined amount of inert gas is continuously supplied from each one of the inert gas supply nozzles 36, 46, 56 and 66, and a predetermined amount of air is continuously exhausted through each one of the exhaust ducts 37a, 47a, 57a and 67a. The valves 36b, 46b, 56b and 66b, and 37b, 47b, 57b and 67b may alternatively be flow controllable valves. In this case, the controller 9 may so controls opening and closing of each valve that the amount of exhaust emission and the amount of inert gas to be supplied are controlled according to whether the open/close mechanisms 21, 31, 41, 51 and 61 are in an open state or a closed state, or process development of the substrates W. By way of example, with the intention of preventing entry of an external atmosphere, a large amount of inert gas may be supplied from the inert gas supply nozzles 66 and 36 when the open/close mechanisms 21 and 31 are in an open state. In other cases, the amount of inert gas to be supplied therefrom may be small. As another example, with the intention of preventing diffusion of an atmosphere containing vapor of a liquid chemical to the outside of a substrate processing apparatus, a large amount of air may be exhausted through the exhaust ducts 47a and 57a when the open/close mechanisms 41 and 51 are in an open state. In other cases, exhaust emissions therethrough may be small.

In the preferred embodiment discussed above, dry process proceeds with condensation of vapor of an organic solvent on the surfaces of the substrates W, and evaporation of this vapor together with water content in the surfaces of the substrates W. As an alternative way of drying the substrates W, the atmosphere in the rinse and dry processing chamber 3 may be subjected to pressure reduction to reach a level of an atmospheric pressure or lower. As another alternative way, the substrates W may be dried by spraying the surfaces of the substrates W with a heated inert gas, for example.

<4. Alternative Transportation Modes>

In the preferred embodiment discussed above, the substrates W are transported by the two transport mechanisms including 70 (first transport means) and 65 (second transport means), and the three up and down mechanisms including 45 (third transport means), 35 (fourth transport means), and 55. As long as the same path as in the foregoing preferred embodiment is followed to transport the substrates W, alternative transportation modes are applicable. Various types of alternative transportation modes of the substrates W will be discussed next.

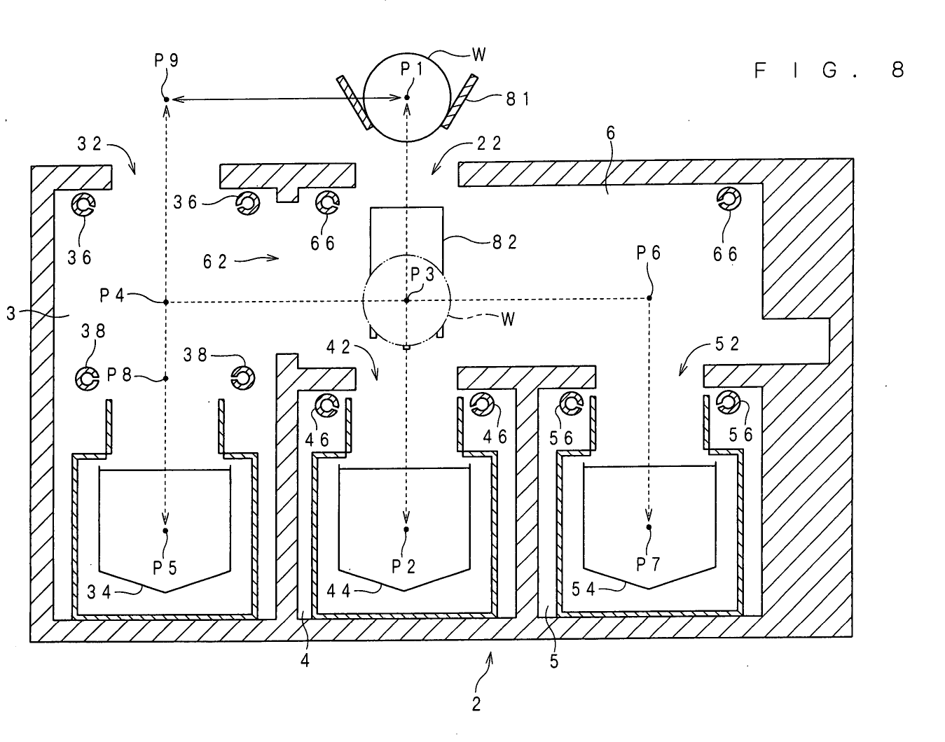

In the following, alternative transportation modes will be discussed with reference to FIGS. 8 through 12 from which the sliding doors 21b, 31b, 41b, 51b and 61b are omitted for the convenience of description. The sliding doors 21b, 31b, 41b, 51b and 61b, and the doors 33b, 43b and 53b are in an open state only when each transport mechanism to be discussed below is to pass therethrough, and are in a closed state in other cases. During process of the substrates W, the inert gas supply nozzles 36, 46, 56 and 66 each continuously supply a predetermined amount of inert gas, and a predetermined amount of air is continuously exhausted through each one of the exhaust ducts 37a, 47a, 57a and 67a (see FIG. 4).

<4-1. First Alternative Transportation Mode>

As a first alternative transportation mode, two transport mechanisms including 81 (first transport means) and 82 (second transport means) as shown in FIG. 8 are responsive to transportation of the substrates W. The transport mechanism 81 serves to transport the substrates W to and from another apparatus. The transport mechanism 81 moves between a position above the liquid chemical processing chamber 2 and a position above the rinse and dry processing chamber 3, which path is shown by an arrowed solid line in FIG. 8. The transport mechanism 82 moves between a position above the substrate inlet 22, the first liquid chemical bath 44, the second liquid chemical bath 54, the rinse bath 34, and a position above the rinse and dry processing chamber 3 while passing through the substrate inlet and outlet 22 and 32, and the opening 62, which path is shown by arrowed dashed lines in FIG. 8. Up and down and lateral movement of the transport mechanism 82 is realized by a drive mechanism not shown such as a rail. Similar to the transport mechanism 70 discussed above, the transport mechanism 81 has a pair of holding plates for holding the substrates W in an upright posture from the sides. Similar to the up and down mechanisms 35, 45 and 55 discussed above, the transport mechanism 82 has three holding rods for holding the substrates W in an upright posture from underneath. Hence, the substrates W can be transferred to and from the transport mechanisms 81 and 82 without interference therebetween.

When the substrates W are to be processed in a substrate processing apparatus comprising the transport mechanisms 81 and 82, the following steps are followed for transportation of the substrates W. First, the unprocessed substrates W are transported by the transport mechanism 81 to the position P1 above the substrate inlet 22. Next, the transport mechanism 82 moves up through the substrate inlet 22 to the position P1. The transport mechanism 81 thereafter releases the substrates W and the transport mechanism 82 receives the substrates W from underneath, whereby the substrates W are transferred from the transport mechanism 81 to the transport mechanism 82 at the position P1.

The transport mechanism 82 holding the substrates W thereon moves down through the substrate inlet 22 and the opening 42 to the position P2 in the first liquid chemical bath 44, at which the substrates W are dipped into a liquid chemical stored in the first liquid chemical bath 44. The transport mechanism 82 is brought to a standstill or oscillates at the position P2 for a certain period of time, whereby the substrates W are subjected to liquid chemical process.

At the time when a certain period of time has elapsed and the liquid chemical process in the first liquid chemical bath 44 is finished, the transport mechanism 82 holding the substrates W thereon rises up through the opening 42 to the position P3 in the substrate transport chamber 6. The transport mechanism 82 thereafter laterally moves to the position P6 in the substrate transport chamber 6 above the opening 52. The transport mechanism 82 continues to move down through the opening 52 to the position P7 in the second liquid chemical bath 54, at which the substrates W are dipped into a liquid chemical stored in the second liquid chemical bath 54. The transport mechanism 82 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the transport mechanism 82 holding the substrates W thereon rises up through the opening 52 to the position P6. The transport mechanism 82 then laterally moves to the position P4 in the rinse and dry processing chamber 3 through the opening 62, thereafter moving down to the position P5 in the rinse bath 34, at which the substrates W are dipped into pure water stored in the rinse bath 34. The transport mechanism 82 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the transport mechanism 82 holding the substrates W thereon rises up to the position P8 between the organic solvent supply nozzles 38, at which the substrates W are subjected to dry process by means of supply of vapor of an organic solvent from the organic solvent supply nozzles 68. This dry process proceeds with condensation of the vapor of the supplied organic solvent on the surfaces of the substrates W, and evaporation of this vapor together with water content in the surfaces of the substrates W.

At the time when the dry process of the substrates W is finished, the transport mechanism 82 holding the substrates W thereon moves up through the substrate outlet 32 to the position P9 above the substrate outlet 32. The processed substrates W are then transferred from the transport mechanism 82 to the transport mechanism 81 placed in standby at the position P9. A series of processes thereby ends.

In the first alternative transportation mode, the transport mechanism 82 is alone responsive to a series of transport operations of the substrates W starting from receipt of the substrates W from the transport mechanism 82 and ending with transfer of the processed substrates W to the transport mechanism 81. As a result, a less number of transfer operations of the substrates W are required, to thereby reduce the probability of dust generation as a result of transfer operations of the substrates W.

<4-2. Second Alternative Transportation Mode>

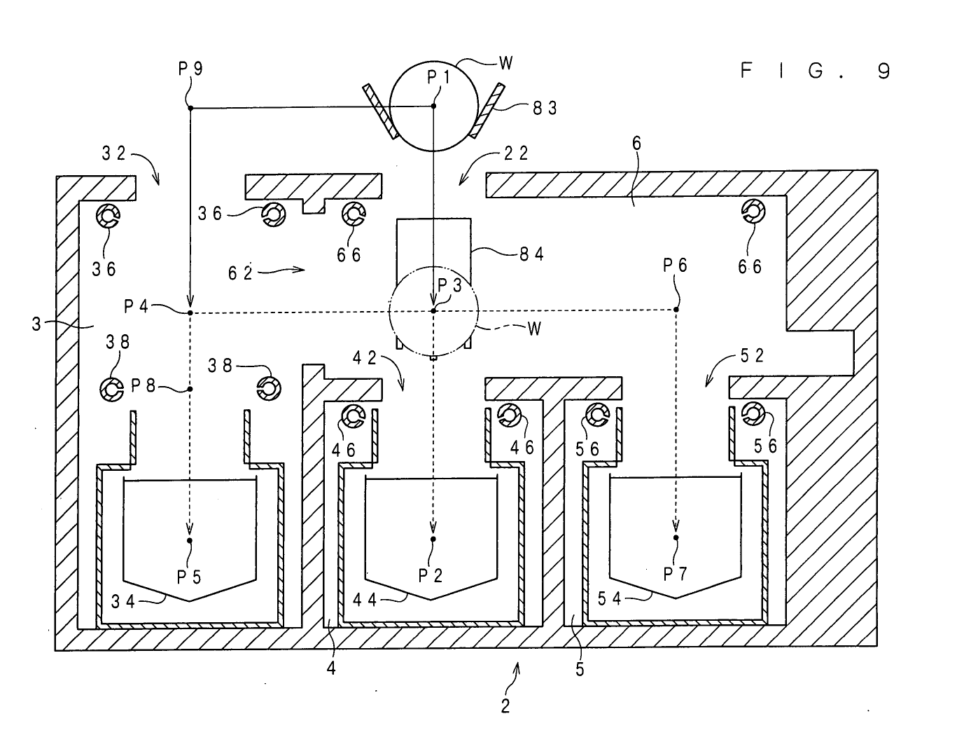

As a second alternative transportation mode, two transport mechanisms including 83 (first transport means) and 84 (second transport means) as shown in FIG. 9 may be responsive to transportation of the substrates W. The transport mechanism 83 serves to transport the substrates W to and from another apparatus. The transport mechanism 83 moves between the liquid chemical processing chamber 2, a position above the liquid chemical processing chamber 2, a position above the rinse and dry processing chamber 3, and the rinse and dry processing chamber 3 while passing through the substrate inlet and outlet 22 and 32, which path is shown by arrowed solid lines in FIG. 9. The transport mechanism 84 moves between the first and second liquid chemical baths 44 and 54, and the rinse bath 34 through the opening 62, which path is shown by arrowed dashed lines in FIG. 9. Up and down and lateral movement of each of the transport mechanisms 83 and 84 is realized by a drive mechanism not shown such as a rail. Similar to the transport mechanism 70 discussed above, the transport mechanism 83 has a pair of holding plates for holding the substrates W in an upright posture from the sides. Similar to the up and down mechanisms 35, 45 and 55 discussed above, the transport mechanism 84 has three holding rods for holding the substrates W in an upright posture from underneath. Hence, the substrates W can be transferred to and from the transport mechanisms 83 and 84 without interference therebetween.

When the substrates W are to be processed in a substrate processing apparatus comprising the transport mechanisms 83 and 84, the following steps are followed for transportation of the substrates W. First, the unprocessed substrates W are transported by the transport mechanism 83 to the position P1 above the substrate inlet 22. Next, the transport mechanism 83 moves to the position P3 through the substrate inlet 22, at which the transport mechanism 84 is previously placed in standby. The transport mechanism 83 releases the substrates W and the transport mechanism 84 receives the substrates W from underneath, whereby the substrates W are transferred from the transport mechanism 83 to the transport mechanism 84.

The transport mechanism 83 holding the substrates W thereon moves down through the opening 42 to the position P2 in the first liquid chemical bath 44, at which the substrates W are dipped into a liquid chemical stored in the first liquid chemical bath 44. The transport mechanism 84 is brought to a standstill or oscillates at the position P2 for a certain period of time, whereby the substrates W are subjected to liquid chemical process.

During the liquid chemical process in the first liquid chemical bath 44, the transport mechanism 83 moves up to return to the position P1 through the substrate inlet 22, then further moving laterally to the position P9. The transport mechanism 83 is placed in standby at the position P9.

At the time when a certain period of time has elapsed and the liquid chemical process in the first liquid chemical bath 44 is finished, the transport mechanism 84 holding the substrates W thereon moves up through the opening 42 to the position P3 in the substrate transport chamber 6. The transport mechanism 84 thereafter laterally moves to the position P6 in the substrate transport chamber 6 above the opening 52. The transport mechanism 84 continues to move down through the opening 52 to the position P7 in the second liquid chemical bath 54, at which the substrates W are dipped into a liquid chemical stored in the second liquid chemical bath 54. The transport mechanism 84 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the transport mechanism 84 holding the substrates W thereon moves up through the opening 52 to the position P6. The transport mechanism 84 thereafter moves laterally to the position P4 in the rinse and dry processing chamber 3 through the opening 62. The transport mechanism 84 continues to move down to the position PS in the rinse bath 34, at which the substrates W are dipped into pure water stored in the rinse bath 34. The transport mechanism 84 is brought to a standstill or oscillates at the position PS for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the transport mechanism 84 holding the substrates W thereon rises up to the position P8 between the organic solvent supply nozzles 38, at which the substrates W are subjected to dry process by means of supply of vapor of an organic solvent from the organic solvent supply nozzles 38. This dry process proceeds with condensation of the vapor of the supplied organic solvent on the surfaces of the substrates W, and evaporation of this vapor together with water content in the surfaces of the substrates W.

At the time when the dry process of the substrates W is finished, the transport mechanism 84 holding the substrates W thereon moves up to the position P4 while the transport mechanism 83 placed in standby at the position P9 moves down to the position P4 through the substrate outlet 32. By means of rotation of the holding plates, the transport mechanism 83 receives the substrates W held on the transport mechanism 84, whereby the substrates W are transferred from the transport mechanism 84 to the transport mechanism 83 at the position P4. The transport mechanism 83 holding the substrates W thereafter moves up through the substrate outlet 32 to the position P9 above the substrate outlet 32. A series of processes thereby ends.

In the second alternative transportation mode, two transport mechanisms including 83 and 84 are responsive to transportation of the substrates W. As a result, a less number of transfer operations of the substrates W are required, to thereby reduce the probability of dust generation as a result of transfer operations of the substrates W.

<4-3. Third Alternative Transportation Mode>

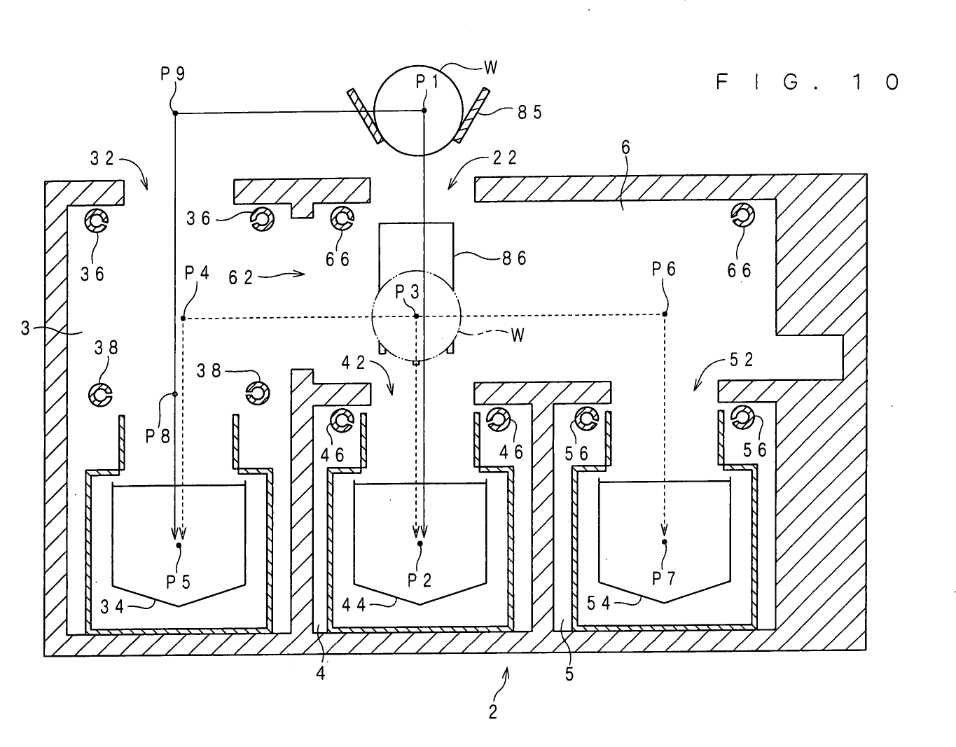

As a third alternative transportation mode, two transport mechanisms including 85 (first transport means) and 86 (second transport means) as shown in FIG. 10 are responsive to transportation of the substrates W. The transport mechanism 85 serves to transport the substrates W to and from another apparatus. The transport mechanism 85 moves between the first liquid chemical bath 44, a position above the liquid chemical processing chamber 2, a position above the rinse and dry processing chamber 3, and the rinse bath 34 while passing through the substrate inlet and outlet 22 and 32, which path is shown by arrowed solid lines in FIG. 10. The transport mechanism 86 moves between the first and second liquid chemical baths 44 and 54, and the rinse bath 34 through the opening 62, which path is shown by arrowed dashed lines in FIG. 10. Up and down and lateral movement of each of the transport mechanisms 85 and 86 is realized by a drive mechanism not shown such as a rail. Similar to the transport mechanism 70 discussed above, the transport mechanism 85 has a pair of holding plates for holding the substrates W in an upright posture from the sides. Similar to the up and down mechanisms 35, 45 and 55 discussed above, the transport mechanism 86 has three holding rods for holding the substrates W in an upright posture from underneath. Hence, the substrates W can be transferred to and from the transport mechanisms 85 and 86 without interference therebetween.

When the substrates W are to be processed in a substrate processing apparatus comprising the transport mechanisms 85 and 86, the following steps are followed for transportation of the substrates W. First, the unprocessed substrates W are transported by the transport mechanism 85 to the position P1 above the substrate inlet 22. Next, the transport mechanism 85 moves down through the substrate inlet 22 and the opening 42 to the position P2 in the first liquid chemical bath 44, at which the transport mechanism 86 is previously placed in standby. The transport mechanism 85 releases the substrates W and the transport mechanism 86 receives the substrates W from underneath, whereby the substrates W are transferred from the transport mechanism 85 to the transport mechanism 86. After transfer of the substrates W to the transport mechanism 86, the transport mechanism 85 moves up to return to the position P1 through the opening 42 and the substrate inlet 22, then further laterally moving to the position P9. The transport mechanism 85 is placed in standby at the position P9. The transport mechanism 86 holding the substrates W thereon in the fist liquid chemical bath 44 is brought to a standstill or oscillates at the position P2 for a certain period of time, whereby the substrates W are subjected to liquid chemical process.

Storage of a liquid chemical in the first liquid chemical bath 44 is desirably after completion of transfer of the substrates W from the transport mechanism 85 to the transport mechanism 86, and exit of the transport mechanism 85 upward from the first liquid chemical bath 44. This is because the holding plates of the transport mechanism 85 which transports the processed substrates W later should be prevented from being coated with a liquid chemical.

At the time when a certain period of time has elapsed and the liquid chemical process in the first liquid chemical bath 44 is finished, the transport mechanism 86 holding the substrates W thereon moves up through the opening 42 to the position P3 in the substrate transport chamber 6. The transport mechanism 86 thereafter laterally moves to the position P6 in the substrate transport chamber 6 above the opening 52. The transport mechanism 86 continues to move down through the opening 52 to the position P7 in the second liquid chemical bath 54, at which the substrates W are dipped into a liquid chemical stored in the second liquid chemical bath 54. The transport mechanism 86 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the transport mechanism 86 holding the substrates W thereon moves up through the opening 52 to the position P6. The transport mechanism 86 thereafter moves laterally to the position P4 in the rinse and dry processing chamber 3 through the opening 62. The transport mechanism 86 continues to move down to the position P5 in the rinse bath 34, at which the substrates W are dipped into pure water stored in the rinse bath 34. The transport mechanism 86 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the transport mechanism 85 placed in standby at the position P9 moves down through the substrate outlet 32 to the position P5 in the rinse bath 34. By means of rotation of the holding plates, the transport mechanism 85 receives the substrates W held on the transport mechanism 86, whereby the substrates W are transferred from the transport mechanism 86 to the transport mechanism 85 at the position P5. The transport mechanism 85 desirably enters the rinse bath 34 after drainage of pure water from the rinse bath 34 is completed. This is because the holding plates of the transport mechanism 85 should be prevented from being coated with droplets of the pure water used in rinsing to improve efficiency of dry process of the substrates W.

The transport mechanism 85 holding the substrates W rises up to the position P8 between the organic solvent supply nozzles 38, at which the substrates W are subjected to dry process by means of supply of vapor of an organic solvent from the organic solvent supply nozzles 38. This dry process proceeds with condensation of the vapor of the supplied organic solvent on the surfaces of the substrates W, and evaporation of this vapor together with water content in the surfaces of the substrates W.

At the time when the dry process of the substrates W is finished, the transport mechanism 85 holding the substrates W moves up through the substrate outlet 32 to the position P9 above the substrate outlet 32. A series of processes thereby ends.

In the third alternative transportation mode, two transport mechanisms including 85 and 86 are responsive to transportation of the substrates W. As a result, a less number of transfer operations of the substrates W are required, to thereby reduce the probability of dust generation as a result of transfer operations of the substrates W.

<4-4. Fourth Alternative Transportation Mode>

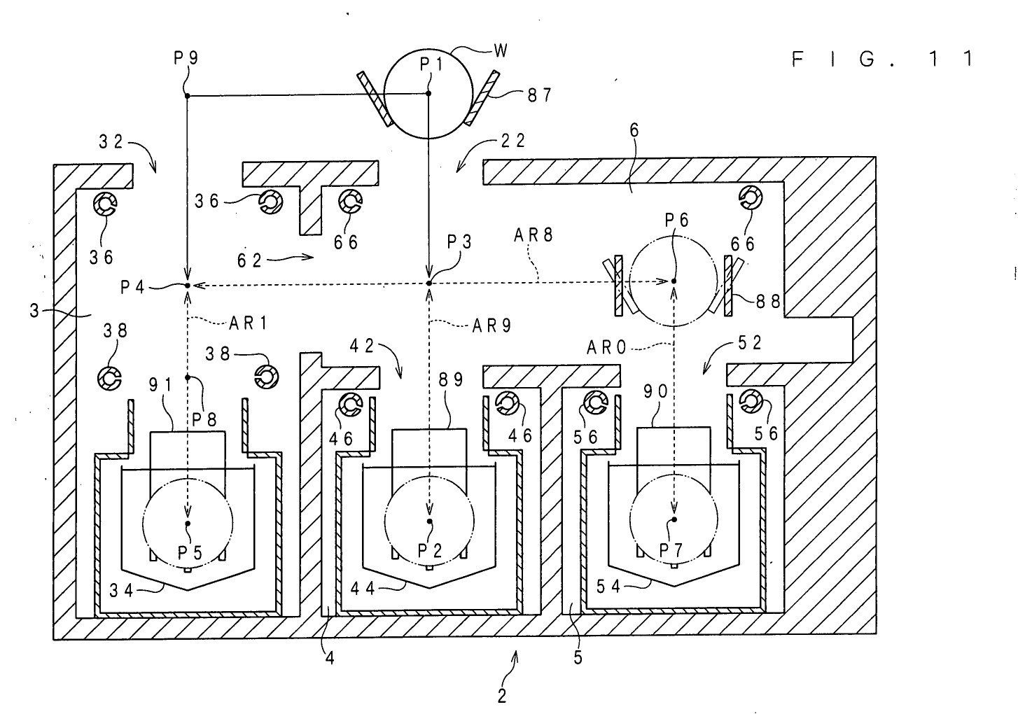

As a fourth alternative transportation mode, five transport mechanisms including 87 (first transport means), 88 (second transport means), 89 and 90 (third transport means), and 91 (fourth transport means) as shown in FIG. 11 are responsive to transportation of the substrates W. The transport mechanism 87 serves to transport the substrates W to and from another apparatus. The transport mechanism 87 moves between the liquid chemical processing chamber 2, a position above the liquid chemical processing chamber 2, a position above the rinse and dry processing chamber 3, and the rinse and dry processing chamber 3 while passing through the substrate inlet and outlet 22 and 32, which path is shown by arrowed solid lines in FIG. 11. The transport mechanism 88 carries the substrates W between the liquid chemical processing chamber 2 and the rinse and dry processing chamber 3 through the opening 62, which path is shown by an arrowed dashed line AR8 in FIG. 11. The transport mechanism 89 carries the substrates W in the liquid chemical processing chamber 2 between a position inside the first liquid chemical bath 44 and a position outside the first liquid chemical bath 44, which path is shown by an arrowed dashed line AR9 in FIG. 11. The transport mechanism 90 carries the substrates W in the liquid chemical processing chamber 2 between a position inside the second liquid chemical bath 54 and a position outside the second liquid chemical bath 54, which path is shown by an arrowed dashed line AR0 in FIG. 11. The transport mechanism 91 carries the substrates W in the rinse and dry processing chamber 3 between a position inside the rinse bath 34 and a position outside the rinse bath 34, which path is shown by an arrowed dashed line AR1 in FIG. 11. Up and down and lateral movement of the transport mechanism 87 is realized by a drive mechanism not shown such as a rail. Similar to the transport mechanism 70 discussed above, the transport mechanisms 87 and 88 each have a pair of holding plates for holding the substrates W in an upright posture from the sides. Similar to the up and down mechanisms 35, 45 and 55 discussed above, the transport mechanisms 89, 90 and 91 each have three holding rods for holding the substrates W in an upright posture from underneath. Hence, the substrates W can be transferred to and from the transport mechanisms 87 and 88, and the transport mechanisms 89, 90 and 91 without interference therebetween.

When the substrates W are to be processed in a substrate processing apparatus comprising the transport mechanisms 87, 88, 89, 90 and 91, the following steps are followed for transportation of the substrates W. First, the unprocessed substrates W are transported by the transport mechanism 87 to the position P1 above the substrate inlet 22. Next, the transport mechanism 87 moves down through the substrate inlet 22 to the position P3 in the liquid chemical processing chamber 2, at which the transport mechanism 89 is previously placed in standby. The transport mechanism 87 releases the substrates W and the transport mechanism 89 receives the substrates W from underneath, whereby the substrates W are transferred from the transport mechanism 87 to the transport mechanism 89 at the position P3.

The transport mechanism 89 holding the substrates W thereon moves down through the opening 42 to the position P2 in the first liquid chemical bath 44, at which the substrates W are dipped into a liquid chemical stored in the first liquid chemical bath 44. The transport mechanism 89 is brought to a standstill or oscillates at the position P2 for a certain period of time, whereby the substrates W are subjected to liquid chemical process.

During the liquid chemical process in the first liquid chemical bath 44, the transport mechanism 87 moves up to return to the position P1 through the substrate inlet 22, then further moving laterally to the position P9. The transport mechanism 87 is placed in standby at the position P9.

During the liquid chemical process in the first liquid chemical bath 44, the transport mechanism 88 moves to the position P3 above the opening 42 and is placed in standby at the position P3. At the time when a certain period of time has elapsed and the liquid chemical process in the first liquid chemical bath 44 is finished, the transport mechanism 89 holding the substrates W thereon moves up through the opening 42 to the position P3 in the substrate transport chamber 6. By means of rotation of the holding plates, the transport mechanism 88 receives the substrates W held on the transport mechanism 89, whereby the substrates W are transferred from the transport mechanism 89 to the transport mechanism 88 at the position P3. After transfer of the substrates W to the transport mechanism 88, the transport mechanism 89 moves down to a position that does not interfere with lateral movement of the transport mechanism 88.

The transport mechanism 88 holding the substrates W moves laterally to the position P6 in the substrate transport chamber 6 above the opening 52. The transport mechanism 90 thereafter moves up to the position P6. By means of rotation of the holding plates, the transport mechanism 88 releases the substrates W and the transport mechanism 90 receives the substrates W from underneath, whereby the substrates W are transferred from the transport mechanism 88 to the transport mechanism 90 at the position P6.

The transport mechanism 90 holding the substrates W thereon moves down through the opening 52 to the position P7 in the second liquid chemical bath 54, at which the substrates W are dipped into a liquid chemical stored in the second liquid chemical bath 54. The transport mechanism 90 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the transport mechanism 90 holding the substrates W thereon moves up through the opening 52 to the position P6 at which the transport mechanism 88 is placed in standby. By means of rotation of the holding plates, the transport mechanism 88 receives the substrates W held on the transport mechanism 90, whereby the substrates W are transferred from the transport mechanism 90 to the transport mechanism 88 at the position P6. After transfer of the substrates W to the transport mechanism 88, the transport mechanism 90 moves down to a position that does not interfere with lateral movement of the transport mechanism 88.

The transport mechanism 88 holding the substrates W thereafter moves laterally through the opening 62 to the position P4 in the rinse and dry processing chamber 3. Next, the transport mechanism 91 moves up to the position P4. By means of rotation of the holding plates, the transport mechanism 88 releases the substrates W and the transport mechanism 91 receives the substrates W from underneath, whereby the substrates W are transferred from the transport mechanism 88 to the transport mechanism 90 at the position P4.

The transport mechanism 91 holding the substrates W thereon moves down to the position P5 in the rinse bath 34, at which the substrates W are dipped into pure water stored in the rinse bath 34. The transport mechanism 91 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the transport mechanism 91 holding the substrates W thereon rises up to the position P8 between the organic solvent supply nozzles 38, at which the substrates W are subjected to dry process by means of supply of vapor of an organic solvent from the organic solvent supply nozzles 38. This dry process proceeds with condensation of the vapor of the supplied organic solvent on the surfaces of the substrates W, and evaporation of this vapor together with water content in the surfaces of the substrates W.

At the time when the dry process of the substrates W is finished, the transport mechanism 91 holding the substrates W thereon moves up to the position P4, whereas the transport mechanism 87 placed in standby at the position P9 moves down through the substrate outlet 32 to the position P4. By means of rotation of the holding plates, the transport mechanism 87 receives the substrates W held on the transport mechanism 91, whereby the substrates W are transferred from the transport mechanism 91 to the transport mechanism 87 at the position P4. The transport mechanism 87 holding the substrates W thereafter moves up through the substrate outlet 32 to the position P9 above the substrate outlet 32. A series of processes thereby ends.

<4-5. Fifth Alternative Transportation Mode>

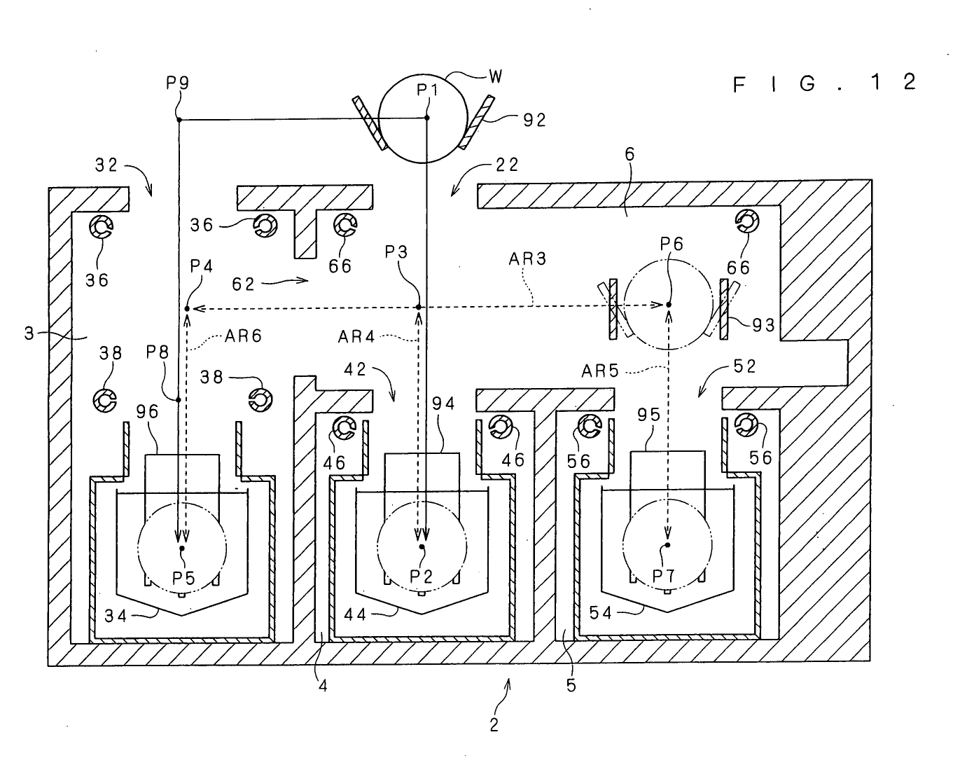

As a fifth alternative transportation mode, five transport mechanisms including 92 (first transport means), 93 (second transport means), 94 and 95 (third transport means), and 96 (fourth transport means) as shown in FIG. 12 are responsive to transportation of the substrates W. The transport mechanism 92 serves to transport the substrates W to and from another apparatus. The transport mechanism 92 moves between the first liquid chemical bath 44, a position above the liquid chemical processing chamber 2, a position above the rinse and dry processing chamber 3, and the rinse bath 34 while passing through the substrate inlet and outlet 22 and 32, which path is shown by arrowed solid lines in FIG. 12. The transport mechanism 93 carries the substrates W between the liquid chemical processing chamber 2 and the rinse and dry processing chamber 3 through the opening 62, which path is shown by an arrowed dashed line AR3 in FIG. 12. The transport mechanism 94 carries the substrates W in the liquid chemical processing chamber 2 between a position inside the first liquid chemical bath 44 and a position outside the first liquid chemical bath 44, which path is shown by an arrowed dashed line AR4 in FIG. 12. The transport mechanism 95 carries the substrates W in the liquid chemical processing chamber 2 between a position inside the second liquid chemical bath 54 and a position outside the second liquid chemical bath 54, which path is shown by an arrowed dashed line AR5 in FIG. 12. The transport mechanism 96 carries the substrates W in the rinse and dry processing chamber 3 between a position inside the rinse bath 34 and a position outside the rinse bath 34, which path is shown by an arrowed dashed line AR6 in FIG. 12. Up and down and lateral movement of the transport mechanism 92 is realized by a drive mechanism not shown such as a rail. Similar to the transport mechanism 70 discussed above, the transport mechanisms 92 and 93 each have a pair of holding plates for holding the substrates W in an upright posture from the sides. Similar to the up and down mechanisms 35, 45 and 55 discussed above, the transport mechanisms 94, 95 and 96 each have three holding rods for holding the substrates W in an upright posture from underneath. Hence, the substrates W can be transferred to and from the transport mechanisms 92 and 93, and the transport mechanisms 94, 95 and 96 without interference therebetween.

When the substrates W are to be processed in a substrate processing apparatus comprising the transport mechanisms 92, 93, 94, 95 and 96, the following steps are followed for transportation of the substrates W. First, the unprocessed substrates W are transported by the transport mechanism 92 to the position P1 above the substrate inlet 22. Next, the transport mechanism 92 moves down through the substrate inlet 22 and the opening 42 to the position P2 in the first liquid chemical bath 44, at which the transport mechanism 94 is previously placed in standby. The transport mechanism 92 releases the substrates W and the transport mechanism 94 receives the substrates W from underneath, whereby the substrates W are transferred from the transport mechanism 92 to the transport mechanism 94 at the position P2. The transport mechanism 92 thereafter moves up through the opening 42 and the substrate inlet 22 to return to the position P1, then further moving laterally to the position P9. The transport mechanism 92 is placed in standby at the position P9. The transport mechanism 94 holding the substrates W thereon in the first liquid chemical bath 44 is brought to a standstill or oscillates at the position P2 for a certain period of time, whereby the substrates W are subjected to liquid chemical process.

Storage of a liquid chemical in the first liquid chemical bath 44 is desirably after completion of transfer of the substrates W from the transport mechanism 92 to the transport mechanism 94, and exit of the transport mechanism 92 upward from the first liquid chemical bath 44. This is because the holding plates of the transport mechanism 92 which transports the processed substrates W later should be prevented from being coated with a liquid chemical.

During the liquid chemical process in the first liquid chemical bath 44, the transport mechanism 93 moves to the position P3 above the opening 42. The transport mechanism 93 is placed in standby at the position P3. At the time when a certain period of time has elapsed and the liquid chemical process in the first liquid chemical bath 44 is finished, the transport mechanism 94 holding the substrates W thereon moves up through the opening 42 to the position P3 in the substrate transport chamber 6. By rotation of the holding plates, the transport mechanism 93 receives the substrates W held on the transport mechanism 94, whereby the substrates W are transferred from the transport mechanism 94 to the transport mechanism 93 at the position P3. After transfer of the substrates W to the transport mechanism 93, the transport mechanism 94 moves down to a position that does not interfere with lateral movement of the transport mechanism 93.

The transport mechanism 93 holding the substrates W moves laterally to the position P6 in the substrate transport chamber 6 above the opening 52. Thereafter, the transport mechanism 95 moves up to the position P6. By means of rotation of the holding plates, the transport mechanism 93 releases the substrates W and the transport mechanism 95 receives the substrates W from underneath, whereby the substrates W are transferred from the transport mechanism 93 to the transport mechanism 95 at the position P6.

The transport mechanism 95 holding the substrates W thereon moves down through the opening 52 to the position P7 in the second liquid chemical bath 54, at which the substrates W are dipped into a liquid chemical stored in the second liquid chemical bath 54. The transport mechanism 95 is brought to a standstill or oscillates at the position P7 for a certain period of time, whereby the substrates W are subjected to liquid chemical process.

At the time when a certain period of time has elapsed and the liquid chemical process in the second liquid chemical bath 54 is finished, the transport mechanism 95 holding the substrates W thereon moves up through the opening 52 to the position P6 at which the transport mechanism 93 is placed in standby. By means of rotation of the holding plates, the transport mechanism 93 receives the substrates W held on the transport mechanism 95, whereby the substrates W are transferred from the transport mechanism 95 to the transport mechanism 93 at the position P6. After transfer of the substrates W to the transport mechanism 93, the transport mechanism 95 moves down to a position that does not interfere with lateral movement of the transport mechanism 93.

The transport mechanism 93 holding the substrates W moves laterally through the opening 62 to the position P4 in the rinse and dry processing chamber 3. Next, the transport mechanism 96 moves up to the position P4. By means of rotation of the holding plates, the transport mechanism 93 releases the substrates W and the transport mechanism 96 receives the substrates W from underneath, whereby the substrates W are transferred from the transport mechanism 93 to the transport mechanism 96 at the position P4.

The transport mechanism 96 holding the substrates W thereon moves down to the position P5 in the rinse bath 34, at which the substrates W are dipped into pure water stored in the rinse bath 34. The transport mechanism 96 is brought to a standstill or oscillates at the position P5 for a certain period of time, whereby the liquid chemical adhered to the surfaces of the substrates W is washed away, that is, the substrates W are subjected to rinsing.

At the time when a certain period of time has elapsed and the rinsing in the rinse bath 34 is finished, the transport mechanism 92 placed in standby at the position P9 moves down through the substrate outlet 32 to the position P5 in the rinse bath 34. By means of rotation of the holding plates, the transport mechanism 92 receives the substrates W held on the transport mechanism 96, whereby the substrates W are transferred from the transport mechanism 96 to the transport mechanism 92 at the position P5. The transport mechanism 92 desirably enters the rinse bath 34 after drainage of pure water from the rinse bath 34 is completed. This is because the holding plates of the transport mechanism 92 should be prevented from being coated with droplets of the pure water used in rinsing to improve efficiency of dry process of the substrates W.

The transport mechanism 92 holding the substrates W thereafter rises up to the position P8 between the organic solvent supply nozzles 38, at which the substrates W are subjected to dry process by means of supply of vapor of an organic solvent from the organic solvent supply nozzles 38. This dry process proceeds with condensation of the vapor of the supplied organic solvent on the surfaces of the substrates W, and evaporation of this vapor together with water content in the surfaces of the substrates W.

At the time when the dry process of the substrates W is finished, the transport mechanism 92 holding the substrates W moves up through the substrate outlet 32 to the position P9 above the substrate outlet 32. A series of processes thereby ends.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between a position above said first processing chamber and a position above said second processing chamber;
a second transport mechanism for carrying substrates between said first and second processing chambers through said third opening;
a third transport mechanism for carrying substrates between said position above first processing chamber and said liquid chemical processing part through said first opening, said third transport mechanism also transferring substrates between said first and second transport mechanisms; and
a fourth transport mechanism for carrying substrates between said position above said second processing chamber and said pure water processing part through said second opening, said fourth transport mechanism also transferring substrates between said first and second transport mechanisms.

2. The substrate processing apparatus according to claim 1,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

3. The substrate processing apparatus according to claim 2,
wherein said liquid chemical processing part includes a plurality of liquid chemical baths.

4. The substrate processing apparatus according to claim 3,
wherein said liquid chemical processing chamber is divided into a plurality of liquid chemical process units including respective ones of said plurality of liquid chemical baths, and
wherein atmospheres in said plurality of liquid chemical process units can be isolated from each other.

5. The substrate processing apparatus according to claim 4, further comprising:
an inert gas supply member for supplying an inert gas to said first and second processing chambers; and
an exhaust member through which air is exhausted from said first and second processing chambers.

6. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between a position above said first processing chamber and a position above said second processing chamber; and
a second transport mechanism for carrying substrates between said position above said first processing chamber, said liquid chemical processing part, said pure water processing part, and said position above said second processing chamber while passing through said first, second and third openings, said second transport mechanism also transferring substrates to and from said first transport mechanism.

7. The substrate processing apparatus according to claim 6,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

8. The substrate processing apparatus according to claim 7,
wherein said liquid chemical processing part includes a plurality of liquid chemical baths.

9. The substrate processing apparatus according to claim 8,
wherein said liquid chemical processing chamber is divided into a plurality of liquid chemical process units including respective ones of said plurality of liquid chemical baths, and
wherein atmospheres in said plurality of liquid chemical process units can be isolated from each other.

10. The substrate processing apparatus according to claim 9, further comprising:
an inert gas supply member for supplying an inert gas to said first and second processing chambers; and
an exhaust member through which air is exhausted from said first and second processing chambers.

11. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between said first processing chamber, a position above said first processing chamber, a position above said second processing chamber, and said second processing chamber while passing through said first and second openings; and
a second transport mechanism for carrying substrates between said liquid chemical processing part and said pure water processing part through said third opening, said second transport mechanism also transferring substrates to and from said first transport mechanism.

12. The substrate processing apparatus according to claim 11,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

13. The substrate processing apparatus according to claim 12,
wherein said liquid chemical processing part includes a plurality of liquid chemical baths.

14. The substrate processing apparatus according to claim 13,
wherein said liquid chemical processing chamber is divided into a plurality of liquid chemical process units including respective ones of said plurality of liquid chemical baths, and
wherein atmospheres in said plurality of liquid chemical process units can be isolated from each other.

15. The substrate processing apparatus according to claim 14, further comprising:
an inert gas supply member for supplying an inert gas to said first and second processing chambers; and
an exhaust member through which air is exhausted from said first and second processing chambers.

16. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between said liquid chemical processing part, a position above said first processing chamber, a position above said second processing chamber, and said pure water processing part while passing through said first and second openings; and
a second transport mechanism for carrying substrates between said liquid chemical processing part and said pure water processing part through said third opening, said second transport mechanism also transferring substrates to and from said first transport mechanism.

17. The substrate processing apparatus according to claim 16,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

18. The substrate processing apparatus according to claim 17,
wherein said liquid chemical processing part includes a plurality of liquid chemical baths.

19. The substrate processing apparatus according to claim 18,
wherein said liquid chemical processing chamber is divided into a plurality of liquid chemical process units including respective ones of said plurality of liquid chemical baths, and
wherein atmospheres in said plurality of liquid chemical process units can be isolated from each other.

20. The substrate processing apparatus according to claim 19, further comprising:
an inert gas supply member for supplying an inert gas to said first and second processing chambers; and
an exhaust member through which air is exhausted from said first and second processing chambers.

21. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between said first processing chamber, a position above said first processing chamber, a position above said second processing chamber, and said second processing chamber while passing through said first and second openings;
a second transport mechanism for carrying substrates between said first and second processing chambers through said third opening;
a third transport mechanism for carrying substrates in said first processing chamber between a position inside said liquid chemical processing part and a position outside said liquid chemical processing part, said third transport mechanism also transferring substrates between said first and second transport mechanisms; and
a fourth transport mechanism for carrying substrates in said second processing chamber between a position inside said pure water processing part and a position outside said pure water processing part, said fourth transport mechanism also transferring substrates between said first and second transport mechanisms.

22. The substrate processing apparatus according to claim 21,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

23. The substrate processing apparatus according to claim 22,
wherein said liquid chemical processing part includes a plurality of liquid chemical baths.

24. The substrate processing apparatus according to claim 23,
wherein said liquid chemical processing chamber is divided into a plurality of liquid chemical process units including respective ones of said plurality of liquid chemical baths, and
wherein atmospheres in said plurality of liquid chemical process units can be isolated from each other.

25. The substrate processing apparatus according to claim 24, further comprising:
an inert gas supply member for supplying an inert gas to said first and second processing chambers; and
an exhaust member through which air is exhausted from said first and second processing chambers.

26. A substrate processing apparatus, comprising:
a first processing chamber capable of being isolated from an external atmosphere, said first processing chamber including a liquid chemical processing part for performing liquid chemical process on substrates;
a second processing chamber capable of being isolated from an external atmosphere, said second processing chamber including a pure water processing part for performing pure water process on substrates, and a dry processing part for performing dry process on substrates;
a first opening provided to an upper portion of said first processing chamber, said first opening allowing substrates to pass therethrough;
a first shutter member for exposing and blocking said first opening;
a second opening provided to an upper portion of said second processing chamber, said second opening allowing substrates to pass therethrough;
a second shutter member for exposing and blocking said second opening;
a third opening provided between said first and second processing chambers, said third opening allowing substrates to pass therethrough;
a third shutter member for exposing and blocking said third opening;
a first transport mechanism for transporting substrates, said first transport mechanism being movable between said liquid chemical processing part, a position above said first processing chamber, a position above said second processing chamber, and said pure water processing part while passing through said first and second openings;
a second transport mechanism for carrying substrates between said first and second processing chambers through said third opening;
a third transport mechanism for carrying substrates in said first processing chamber between a position inside said liquid chemical processing part and a position outside said liquid chemical processing part, said third transport mechanism also transferring substrates between said first and second transport mechanisms; and
a fourth transport mechanism for carrying substrates in said second processing chamber between a position inside said pure water processing part and a position outside said pure water processing part, said fourth transport mechanism also transferring substrates between said first and second transport mechanisms.

27. The substrate processing apparatus according to claim 26,
wherein said first processing chamber comprises:
a liquid chemical processing chamber including said liquid chemical processing part; and
a transport chamber provided with said third opening, said transport chamber allowing transportation of substrates by said second transport mechanism, and
wherein atmospheres in said liquid chemical processing chamber and said transport chamber can be isolated from each other.

28. The substrate processing apparatus according to claim 27,
wherein said liquid chemical processing part includes a plurality of liquid chemical baths.

29. The substrate processing apparatus according to claim 28,
wherein said liquid chemical processing chamber is divided into a plurality of liquid chemical process units including respective ones of said plurality of liquid chemical baths, and
wherein atmospheres in said plurality of liquid chemical process units can be isolated from each other.

30. The substrate processing apparatus according to claim 29, further comprising:
an inert gas supply member for supplying an inert gas to said first and second processing chambers; and
an exhaust member through which air is exhausted from said first and second processing chambers.
